(19) United States
(12) Patent Application Publication
(10) Pub. No.: US 2025/0384926 A1
(43) Pub. Date: Dec. 18, 2025

(54) MAGNETORESISTIVE MEMORY DEVICES INCLUDING DUAL FREE LAYERS AND METHODS FOR MAKING AND OPERATING THE SAME

(71) Applicant: SANDISK TECHNOLOGIES LLC, ADDISON, TX (US)

(72) Inventors: Goran MIHAJLOVIC, San Jose, CA (US); Wonjoon JUNG, San Jose, CA (US); Lei WAN, San Jose, CA (US); Nathan FRANKLIN, San Jose, CA (US)

(21) Appl. No.: 18/790,599

(22) Filed: Jul. 31, 2024

Related U.S. Application Data
(60) Provisional application No. 63/660,812, filed on Jun. 17, 2024.

(51) Int. Cl. G11C 11/56; G11C 11/16; H10B 61/00; H10N 50/01; H10N 50/10; H10N 50/85

(52) U.S. Cl. CPC G11C 11/5607; G11C 11/161; G11C 11/1675; H10B 61/10; H10N 50/01; H10N 50/10; H10N 50/85

(57) ABSTRACT

A magnetoresistive memory cell includes a magnetic polarizer layer having a hard magnetization along a hard magnetization direction, a first magnetic tunnel junction located on a first side of the magnetic polarizer layer and including a first reference layer having a first side facing the magnetic polarizer layer, a first free layer facing a second side of the first reference layer, and a first tunnel barrier layer located between the first free layer and the first reference layer. The memory cell also includes a second magnetic tunnel junction located on a second side of the magnetic polarizer layer and including a second reference layer having a second side facing the magnetic polarizer layer, a second free layer facing a first side of the second reference layer, and a second tunnel barrier layer located between the second free layer and the second reference layer.

### FIELD

The present disclosure relates to the field of non-volatile memory devices, and particularly to magnetoresistive memory devices including dual free layers and methods for making and operating the same.

### BACKGROUND

Spin-transfer torque (STT) refers to an effect in which the orientation of a magnetic layer in a magnetic tunnel junction or spin valve is modified by a spin-polarized current. Generally, electric current is unpolarized with electrons having random spin orientations. A spin polarized current is one in which electrons have a net non-zero spin due to a preferential spin orientation distribution. When the spin-polarized current flows through a free layer of a magnetic tunnel junction or a spin valve, the electrons in the spin-polarized current can transfer at least some of their angular momentum to the free layer, thereby producing a torque on the magnetization of the free layer. When a sufficient amount of spin-polarized current passes through the free layer, spin-transfer torque can flip the magnetization orientation of the free layer. A resistance difference of a magnetic tunnel junction between different magnetization states of the free layer can be employed to store data within the magnetoresistive random access memory (MRAM) cell depending on whether the magnetization of the free layer is parallel or antiparallel to the magnetization of the reference layer.

### SUMMARY

According to an aspect of the present disclosure, a magnetoresistive memory cell includes a magnetic polarizer layer having a hard magnetization along a hard magnetization direction, a first magnetic tunnel junction located on a first side of the magnetic polarizer layer and including a first reference layer having a first side facing the magnetic polarizer layer, a first free layer facing a second side of the first reference layer, and a first tunnel barrier layer located between the first free layer and the first reference layer. The memory cell also includes a second magnetic tunnel junction located on a second side of the magnetic polarizer layer and including a second reference layer having a second side facing the magnetic polarizer layer, a second free layer facing a first side of the second reference layer, and a second tunnel barrier layer located between the second free layer and the second reference layer. The magnetoresistive memory cell is configured to be programmed into three or four different memory states.

According to another aspect of the present disclosure, a method of forming a magnetoresistive memory device comprises forming a layer stack comprising, in order from bottom to top, a first continuous free layer, a first continuous tunnel barrier layer, a first continuous reference layer, a continuous magnetic polarizer layer, a second continuous reference layer, a second continuous tunnel barrier layer, and a second continuous free layer; patterning the second continuous free layer, the second continuous tunnel barrier layer, and the second continuous reference layer into first pillar structures comprising second magnetic tunnel junctions; forming tubular dielectric spacers around the first pillar structures; and patterning the first continuous free layer, the first continuous tunnel barrier layer, the first continuous reference layer, the continuous magnetic polarizer layer using the first pillar structures and the tubular dielectric spacers to form first magnetic tunnel junctions having a smaller horizontal area than the second tunnel junctions.

According to still another aspect of the present disclosure, a magnetoresistive memory device comprising at least one instance of a magnetoresistive memory cell is provided. The magnetoresistive memory cell comprises: a magnetic polarizer layer having a magnetization along a hard magnetization direction; a first magnetic tunnel junction located on a first side of the magnetic polarizer layer and comprising a first reference layer, a first tunnel barrier layer contacting the first reference layer, and a first free layer contacting the first tunnel barrier layer; and a second magnetic tunnel junction located on a second side of the magnetic polarizer layer that is an opposite of the first side and comprising the second reference layer, a second tunnel barrier layer contacting the second reference layer, and a second free layer comprising a negative spin polarization material and contacting the second tunnel barrier layer.

According to even another aspect of the present disclosure, a method of operating a magnetoresistive memory device is provided. The method comprises: providing a magnetoresistive memory cell that includes a magnetic polarizer layer having a magnetization along a hard magnetization direction, a first magnetic tunnel junction underlying the magnetic polarizer layer and comprising a first reference layer, a first tunnel barrier layer, and a first free layer, and a second magnetic tunnel junction overlying the magnetic polarizer layer and comprising a second reference layer, a second tunnel barrier layer, and a second free layer comprising a negative spin polarization material and contacting the second tunnel barrier layer; and performing a programming operation in which magnetization directions of the first free layer and the second free layer in the magnetoresistive memory cell is programmed into a target magnetic configuration that is selected from: a first magnetic configuration in which the first magnetic tunnel junction is in a first parallel state and the second magnetic tunnel junction is in a second parallel state; and a second magnetic configuration in which the first magnetic tunnel junction is in the first antiparallel state and the second magnetic tunnel junction is in the second antiparallel state.

According to further another aspect of the present disclosure, a method of forming a magnetoresistive memory device is provided, which comprises: forming a magnetoresistive memory cell that includes a magnetic polarizer layer having a magnetization along a hard magnetization direction, a first magnetic tunnel junction underlying the magnetic polarizer layer and comprising a first reference layer, a first tunnel barrier layer, and a first free layer, and a second magnetic tunnel junction overlying the magnetic polarizer layer and comprising a second reference layer, a second tunnel barrier layer, and a second free layer comprising a negative spin polarization material and contacting the second tunnel barrier layer; and forming a programming circuit configured to program magnetization directions of the first free layer and the second free layer into a target magnetic configuration that is selected from: a first magnetic configuration in which the first magnetic tunnel junction is in a first parallel state and the second magnetic tunnel junction is in a second parallel state; or a second magnetic configuration in which the first magnetic tunnel junction is in a first antiparallel state and the second magnetic tunnel junction is in a second antiparallel state.

### BRIEF DESCRIPTION OF THE DRAWINGS

FIG. 1 is a schematic vertical cross-sectional view of an exemplary structure after formation of driver circuits, metal interconnect structures embedded in lower-level dielectric material layers, and first conductive lines according to an embodiment of the present disclosure.

FIG. 2 is a schematic vertical cross-sectional view of a first exemplary magnetoresistive memory cell according to a first embodiment of the present disclosure.

FIGS. 3A-3D are schematic vertical cross-sectional views of the first exemplary magnetoresistive memory cell at various magnetic configurations of the magnetization directions of the first free layer and the second free layer according to an embodiment of the present disclosure.

FIGS. 4A-4C are perspective views of various embodiments of the first exemplary magnetoresistive memory cell 100 of the present disclosure. FIG. 4D is a diagram showing the polarity and the relative magnitude of various programming pulses that are employed to program the first exemplary magnetoresistive memory cell 100 of the present disclosure.

FIGS. 5A-5D are combinations of a schematic vertical cross-sectional view and a schematic diagram illustrating electron flow directions and magnitudes of electrical current for programming the first exemplary magnetoresistive memory cell into the various magnetic configurations of the magnetization directions according to an embodiment of the present disclosure.

FIG. 6 schematically illustrates a magnetoresistive memory device including a single magnetoresistive memory cell and an access transistor according to an embodiment of the present disclosure.

FIGS. 7A and 7B are first and second vertical cross-sectional views, respectively, of a region of a first embodiment of the first exemplary structure after formation of a layer stack including a selector material layer, a first continuous free layer, a first continuous tunnel barrier layer, a first continuous reference layer, a first continuous antiferromagnetic coupling layer, a continuous magnetic polarizer layer, a second continuous antiferromagnetic coupling layer, a second continuous reference layer, a second continuous tunnel barrier layer, a second continuous free layer, and a hardmask material layer according to an embodiment of the present disclosure.

FIGS. 8A and 8B are first and second vertical cross-sectional views, respectively, of a region of the first embodiment of the first exemplary structure after patterning the hardmask material layer into patterned hardmask portions according to an embodiment of the present disclosure. FIG. 8C is a top-down view of the region of the first embodiment of the first exemplary structure of FIGS. 8A and 8B.

FIGS. 9A and 9B are first and second vertical cross-sectional views, respectively, of a region of the first embodiment of the first exemplary structure after formation of a two-dimensional array of magnetoresistive memory cells according to an embodiment of the present disclosure.

FIGS. 10A and 10B are first and second vertical cross-sectional views, respectively, of a region of the first embodiment of the first exemplary structure after formation of second conductive lines according to an embodiment of the present disclosure.

FIGS. 11A and 11B are first and second vertical cross-sectional views, respectively, of a region of a second embodiment of the first exemplary structure after patterning the hardmask material layer, the second continuous free layer, the second continuous tunnel barrier layer, the second continuous reference layer, and the second continuous antiferromagnetic coupling layer according to an embodiment of the present disclosure.

FIGS. 12A and 12B are first and second vertical cross-sectional views, respectively, of a region of the second embodiment of the first exemplary structure after formation of tubular dielectric spacers according to an embodiment of the present disclosure.

FIGS. 13A and 13B are first and second vertical cross-sectional views, respectively, of a region of the second embodiment of the first exemplary structure after formation of a two-dimensional array of magnetoresistive memory cells according to an embodiment of the present disclosure.

FIGS. 14A and 14B are first and second vertical cross-sectional views, respectively, of a region of the second embodiment of the first exemplary structure after formation of second conductive lines according to an embodiment of the present disclosure.

FIG. 15 is a first vertical cross-sectional view of the exemplary structure after formation of second conductive lines and upper-level metal interconnect structures and bonding pads according to embodiments of the present disclosure.

FIGS. 16A and 16B are combinations of a schematic vertical cross-sectional view and a schematic diagram illustrating electron flow directions and magnitudes of electrical current for programming a second exemplary magnetoresistive memory cell into two magnetic configurations of the magnetization directions according to a second embodiment of the present disclosure.

FIG. 17 is a plot of voltage difference between high resistance and low resistance states versus bias current for comparative and exemplary magnetoresistive memory cell of the second embodiment of present disclosure.

FIGS. 18A and 18B are combinations of a schematic vertical cross-sectional view and a schematic diagram illustrating electron flow directions and magnitudes of electrical current for programming a third exemplary magnetoresistive memory cell into two magnetic configurations of the magnetization directions according to third embodiment of the present disclosure.

### DETAILED DESCRIPTION

Embodiments of the present disclosure are directed to magnetoresistive memory devices including dual free layers and methods of making and operating the same. Embodiments of the present disclosure can be employed to provide multilevel magnetoresistive memory devices capable of encoding plural (e.g., two) bits per cell and/or spin-transfer torque magnetoresistive memory devices with enhanced read performance.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Traditional magnetoresistive memory cells are designed to store a single bit per cell. To provide a higher data density and faster access speeds, it is advantageous to employ multi-level storage memory devices that are capable of storing more than one data bit per cell.

According to a first aspect of the present disclosure, a multi-level magnetoresistive memory device providing multi-level bit data storage is provided. The multi-level magnetoresistive memory device includes a dual magnetic tunnel junction (MTJ) magnetic configuration which includes two free layers and two reference layers arranged on opposite sides of a shared hard magnetization layer. This arrangement may be employed to double the data storage capacity, while maintaining the same device footprint. The various embodiments of the present disclosure are now described with reference to accompanying drawings.

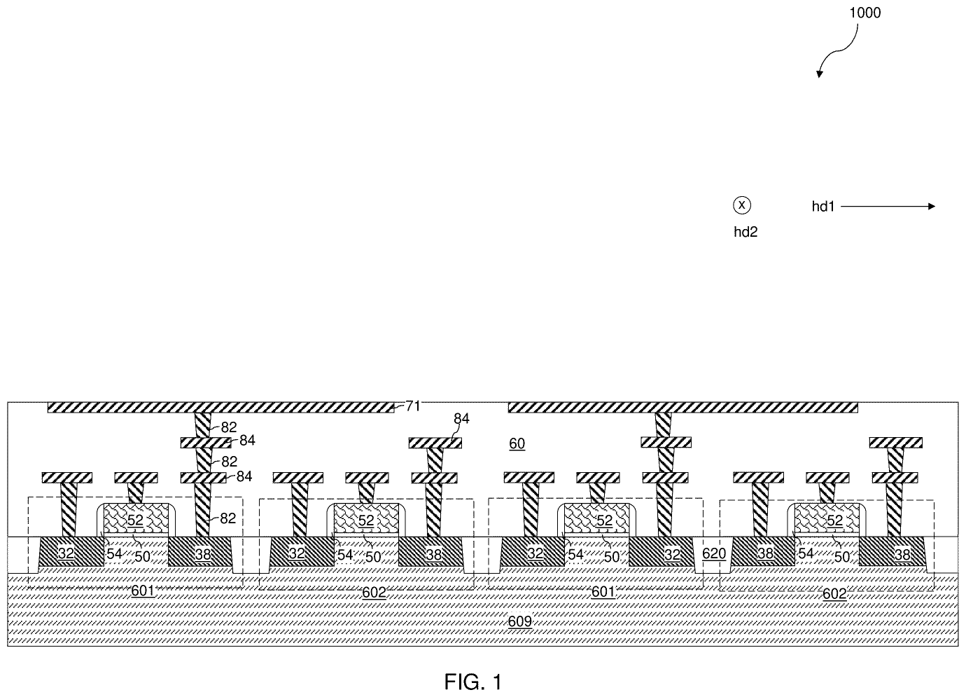

According to FIG. 1, an exemplary structure 1000 according to an embodiment of the present disclosure is illustrated. The exemplary structure 1000 may comprise a substrate, such as a semiconductor substrate 609, various driver circuits (601, 602) for driving access lines of MRAM arrays to be subsequently formed, lower-level metal interconnect structures (82, 84) embedded in lower-level dielectric material layers 60, and first conductive lines 71 laterally extending along a first horizontal direction hd1 and embedded in a topmost dielectric material layer among the lower-level dielectric material layers 60.

As used herein, access lines collectively refer to conductive lines that are electrically connected to a respective row of or to a respective column of MRAM cells. In case the MRAM cells comprise portions of respective MRAM pillar structures, the access lines may contact end surfaces (such as bottom surfaces or top surfaces) of a respective row of MRAM pillar structures or a respective column of MRAM pillar structures. Depending on the magnetic configurations of the driver circuits, access lines may function as word lines or bit lines. Thus, access lines as used herein collective refer to word lines and bit lines. The access lines may comprise an electrically conductive material, such W, Ta, TiN, etc. The first conductive lines 71 function as first access lines for the MRAM array to be subsequently formed.

The various driver circuits (601, 602) comprise field effect transistors and other suitable additional semiconductor devices (not expressly shown) located on, in and/or over the semiconductor substrate 609. The field effect transistors may comprise source regions 32, drain regions 38, gate dielectrics 50, gate electrodes 52, and optional dielectric gate sidewall spacers 54. The additional semiconductor device may comprise any type of semiconductor devices known in the art, such as diodes, resistors, capacitors, etc.

The various driver circuits (601, 602) may comprise, for example, first driver circuits 601 configured to drive the first conductive lines 71 and second driver circuits 602 configured to drive second conductive lines to be subsequently formed in the exemplary structure 1000. The various driver circuits (601, 602) can be configured to enable programming and reading (sensing) operations of the MRAM cells to be subsequently formed in the exemplary structure 1000. The various driver circuits (601, 602) may comprise word line drivers and bit line drivers. The types of circuitry employed for the various driver circuits (601, 602) may be suitably selected based on the type of MRAM cells to be employed in the memory arrays that are subsequently formed in the exemplary structure 1000. For example, if the first conductive lines 71 comprise word lines, then the first driver circuits 601 may comprise word line drivers (i.e., word line switching circuits) for the word lines of the MRAM cells of the exemplary structure 1000, and second driver circuits 602 may comprise bit line drivers (i.e., bit line switching circuits) for the bit lines of MRAM cells of the exemplary structure 1000.

The lower-level metal interconnect structures (82, 84) comprise metal via structures 82 and conductive lines 84. The lower-level metal interconnect structures (82, 84) may comprise any suitable metal or metal alloy, such as copper or copper alloy. The lower-level metal interconnect structures (82, 84) are configured to provide electrical connections between the electrical nodes (e.g., transistor source regions 32 and drain regions 38) of the various driver circuits (601, 602) and the access lines (e.g., word lines or bit lines) of MRAM cells to be subsequently formed.

The lower-level dielectric material layers 60 can include any interlayer dielectric (ILD) material known in the art, which include, for example, undoped silicate glass (i.e., silicon oxide), doped silicate glasses, porous or non-porous silicate glass, dielectric metal oxide materials, silico oxynitride, silicon carbide nitride, etc. The lower-level metal interconnect structures (82, 84) can be formed in the lower-level dielectric material layers 60 employing patterning methods known in the art, which include, but are not limited to, patterning metal layers into the interconnect structures followed by deposition of the lower-level dielectric material layers 60, single damascene metal deposition method in openings in lower-level dielectric material layers 60, dual damascene metal deposition methods in multi-level openings in the lower-level dielectric material layers 60, etc.

A one-dimensional array of first conductive lines 71 are formed within a first dielectric material layer (which may be a topmost dielectric material layer of the lower-level dielectric material layers 60). The first conductive lines 71 comprise conductive lines that laterally extend along the first horizontal direction (e.g., word line direction) hd1 with a uniform pitch along a second horizontal direction (e.g., bit line direction) hd2 that may be perpendicular to the first horizontal direction hd1. The pitch of the first conductive lines 71 along the second horizontal direction hd2 may be about twice the width of each first conductive line 71. The length of the first conductive lines 71 along the first horizontal direction hd1 is determined by the lateral dimensions of the MRAM cells to be subsequently formed and by a total number of the MRAM cells to be connected to each first conductive line 71. In an illustrative example, the total number of the MRAM cells to be connected to a first conductive line 71 may be in a range from 2 to 2¹⁴, although a greater number may also be employed.

The structures formed over the semiconductor substrate 609 may be periodic along the first horizontal direction hd1 and along the second horizontal direction hd2. In this case, the exemplary structure may comprise a two-dimensional periodic repetitions of a unit pattern. A two-dimensional array of magnetoresistive memory cells can be subsequently formed on each one-dimensional array of first conductive lines 71.

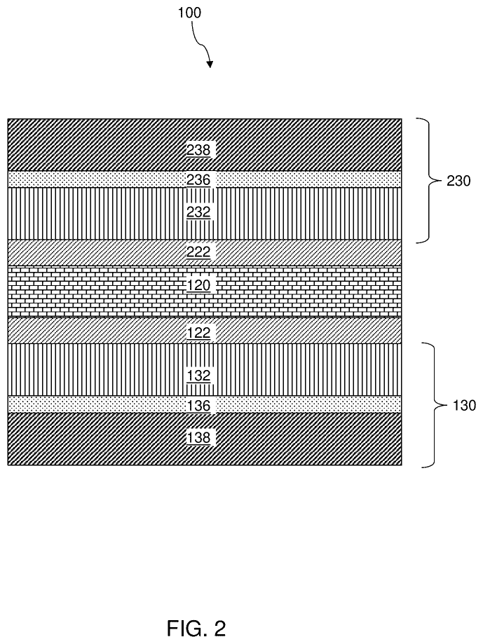

Referring to FIG. 2, a first exemplary magnetoresistive memory cell 100 according to a first embodiment of the present disclosure is illustrated. Specifically, a two-dimensional array of instances of the first exemplary magnetoresistive memory cell 100 can be formed as a two- dimensional magnetoresistive random access memory array on each one-dimensional array of first conductive lines 71 in the exemplary structure of FIG. 1.

The first exemplary magnetoresistive memory cell 100 may comprise a magnetic polarizer layer 120 having a magnetization along an upward or downward magnetization direction; a first reference layer 132 located on a first side of (e.g., underlying) the magnetic polarizer layer 120, antiferromagnetically coupled to the magnetization of the magnetic polarizer layer 120, and having a first fixed magnetization direction that is antiparallel to the magnetization direction of the polarizer layer 120; and a second reference layer 232 located on an opposite second side of (e.g., overlying) the magnetic polarizer layer 120, antiferromagnetically coupled to the magnetization of the magnetic polarizer layer 120, and having a second fixed magnetization direction that is antiparallel to the magnetization direction of the polarizer layer 120. The memory cell 100 also comprises a first magnetic tunnel junction 130 located on the first side of (e.g., underlying) the magnetic polarizer layer 120 and comprising the first reference layer 132, a first free layer 138 that is located on the first side of (e.g., underlies) the first reference layer 132, and a first tunnel barrier layer 136 interposed between the first free layer 138 and the first reference layer 132; and a second magnetic tunnel junction 230 located on the second side of (e.g., overlying) the magnetic polarizer layer 120 and comprising the second reference layer 232, a second free layer 238 that is located on the second side of (e.g., overlies) the second reference layer 232, and a second tunnel barrier layer 236 interposed between the second free layer 238 and the second reference layer 232. While a vertical layer stack is shown in FIG. 2, it should be noted that the stack may have a horizontal orientation with respect to the underlying substrate or an orientation between vertical and horizontal. Furthermore, while an embodiment is described in which the second magnetic tunnel junction 230 overlies the first magnetic tunnel junction 130, alternative embodiments are expressly contemplated herein in which the first magnetic tunnel junction 130 is formed above the second magnetic tunnel junction 230 and the magnetic polarizer layer 120.

According to an aspect of the present disclosure, the first fixed magnetization direction of the first reference layer 132 and the second fixed magnetization direction of the second reference layer 232 are antiparallel to the hard magnetization direction of the magnetic polarizer layer 120. A first antiferromagnetic coupling layer 122 is interposed between the magnetic polarizer layer 120 and the first reference layer 132, and provides antiferromagnetic coupling therebetween. A second antiferromagnetic coupling layer 222 is interposed between the magnetic polarizer layer 120 and the second reference layer 232, and provides antiferromagnetic coupling therebetween. Thus, the first fixed magnetization direction of the first reference layer 132 and the second fixed magnetization direction of the second reference layer 232 are parallel to each other, i.e., are in the same direction. The first fixed magnetization direction of the first reference layer 132 and the second fixed magnetization direction of the second reference layer 232 may point downward or upward in the vertical configuration of FIG. 2.

The magnetic polarizer layer 120 comprises a hard magnetic layer, a ferromagnetic multilayer structure including a superlattice, or a stack of at least one ferromagnetic material layer and at least one antiferromagnetic layer. Alternatively, the magnetic polarizer layer 120 may comprise a synthetic antiferromagnetic (SAF) structure. Generally, the magnetic polarizer layer 120 may comprise any magnetic layer or structure that has permanent primary magnetization direction relative to which the magnetization directions of adjacent magnetic material layers are defined. The magnetization direction of the magnetic polarizer layer 120 is herein referred to as the hard magnetization direction, which may be an upward direction or a downward direction. The magnetic polarizer layer 120 can pin the magnetization direction of the first reference layer 132 and the second reference layer 232.

In one non-limiting illustrative example, the magnetic polarizer layer 120 may comprise a hard magnetic layer (e.g., a permanent magnet layer that retains its magnetism and having an intrinsic coercivity greater than 1000 kAm⁻¹), such as cobalt-platinum alloys, neodymium-iron or neodymium-iron-boron alloys, rare earth-cobalt alloys, iron-aluminum-nickel-cobalt (“alnico”) alloys, ferrite alloys (iron oxide alloys, such as strontium ferrite or barium ferrite), etc. Alnico alloys typically contain 8-12% Al, 15-26% Ni, 5-24% Co, 0-6% Cu, 0-1% Ti, and balance iron, by weight.

In another non-limiting illustrative example, the magnetic polarizer layer 120 may comprise a superlattice of cobalt layers and platinum layers. The number repetitions of a combination of a cobalt layer and a platinum layer may be in a range from 2 to 10, such as from 3 to 6, although lesser and greater number of repetitions may also be employed. In an illustrative example, the cobalt layers may have a respective thickness of 0.2 nm to 0.5 nm, and the platinum layers may have a respective thickness of about 0.1 nm to 0.5 nm. It is understood that a material layer having a thickness that is less than the thickness of a monolayer refers to a discontinuous layer having a fractional coverage that is equal to the ratio of the thickness of the material layer to the thickness of the monolayer.

Each of the antiferromagnetic coupling layers (122, 222) has a material composition and a thickness that provide antiferromagnetic coupling between the magnetic polarizer layer 120 and a respective reference layer (132, 232). Specifically, the first antiferromagnetic coupling layer 122 provides antiferromagnetic coupling between the magnetic polarizer layer 120 and the first reference layer 132, and the second antiferromagnetic coupling layer 222 provides antiferromagnetic coupling between the magnetic polarizer layer 120 and the second reference layer 232. In one embodiment, the antiferromagnetic coupling layer (not illustrated) can include ruthenium or iridium, and can have a thickness in a range from 0.3 nm to 0.8 nm.

Each of the first reference layer 132, the second reference layer 232, the first free layer 138, and the second free layer 238 includes a respective ferromagnetic material, such as CoFeB, CoFe, Co, Ni, NiFe, or a combination thereof. The thickness of each of the first reference layer 132 and the second reference layer 232 may be in a range from 2.5 nm to 10 nm, although lesser and greater thicknesses may also be employed. The thickness of each of the first free layer 138 and the second free layer 238 may be in a range from 1 nm to 3 nm, although lesser and greater thicknesses may also be employed. As will be described in more detail below, the thickness and/or the horizontal area of the first free layer 138 may be different from that of the second free layer 238. Each of the first reference layer 132, the second reference layer 232, the first free layer 138, and the second free layer 238 may be independently deposited using physical vapor deposition (PVD) or atomic layer deposition (ALD).

Each of the tunnel barrier layers (136, 236) includes a dielectric tunnel barrier material. such as magnesium oxide (MgO). In one embodiment, the thickness of each tunnel barrier layer (136, 236) may be in a range from 0.7 nm to 2.4 nm, although lesser and greater thickness may also be employed. Each tunnel barrier layer (136, 236) can be deposited using physical vapor deposition or atomic layer deposition to provide uniform thickness and high-quality coverage. The thicknesses of the first tunnel barrier layer 136 and the second tunnel barrier layer 236 may be either the same or different from each other (so that the magnetic tunnel junctions (130, 230) can provide different levels of tunneling resistance values). For example, the second tunnel barrier layer 236 may be thicker than the first tunnel barrier layer 136.

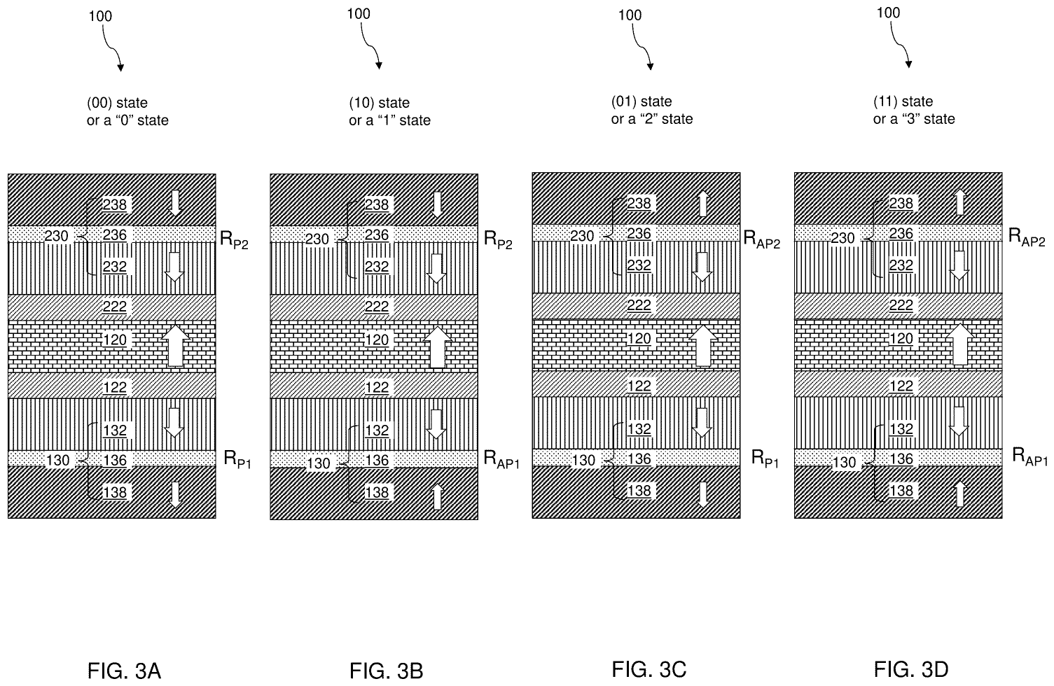

FIGS. 3A-3D are schematic vertical cross-sectional views of the first exemplary magnetoresistive memory cell 100 at various magnetic configurations (e.g., memory states) of the magnetization directions of the first free layer 138 and the second free layer 238 according to an embodiment of the present disclosure.

FIG. 3A illustrates a first magnetic configuration in which the first magnetic tunnel junction 130 is in a parallel state (which is referred to as a first parallel state) and the second magnetic tunnel junction 230 is in a parallel state (which is referred to as a second parallel state). As used herein, a parallel state for a magnetic tunnel junction refers to a state in which the magnetization direction of a free layer is parallel to the magnetization direction of a reference layer, and an antiparallel state for a magnetic tunnel junction refers to a state in which the magnetization direction of a free layer is antiparallel to the magnetization direction of the reference layer. The first magnetic configuration can encode two ordered binary bits of “0” and “0”, and the state of the first magnetic configuration is referred to as a (00) state. The combination of two binary bits constitutes a multi-level memory cell that is capable of encoding four memory levels or states which include a “0” state, a “1” state, a “2” state, and a “3” state. As used herein, a multi-level bit or cell refers to a data bit or cell that can store 3 or more data values. In this instant case, the combination of two binary bits constitutes a quaternary bit, i.e., a bit that is capable of encoding and storing four data values. The first magnetic configuration can encode a “0” state among four possible states.

FIG. 3B illustrates a second magnetic configuration in which the first magnetic tunnel junction 130 is in the antiparallel state (i.e., the first antiparallel state) and the second magnetic tunnel junction 230 is in a parallel state (which is referred to as a second parallel state). The second magnetic configuration can encode two ordered binary bits of “1” and “0”, and the state of the second magnetic configuration is referred to as a (10) state. The second magnetic configuration can encode a “1” state among four possible states.

FIG. 3C illustrates a third magnetic configuration in which the first magnetic tunnel junction 130 is in a parallel state (i.e., the first parallel state) and the second magnetic tunnel junction 230 is in the antiparallel state (i.e., the second antiparallel state). The second magnetic configuration can encode two ordered binary bits of “0” and “1”, and the state of the third magnetic configuration is referred to as a (01) state. The third magnetic configuration can encode a “2” state among four possible states.

FIG. 3D illustrates a fourth magnetic configuration in which the first magnetic tunnel junction 130 is in the antiparallel state (i.e., the first antiparallel state) and the second magnetic tunnel junction 230 is in the antiparallel state (i.e., the second antiparallel state). The second magnetic configuration can encode two ordered binary bits of “1” and “1”, and the state of the first magnetic configuration is referred to as a (11) state. The second magnetic configuration can encode a “3” state among four possible states.

Generally speaking, the antiparallel state resistance of a magnetic tunnel junction is higher than the parallel state resistance of the magnetic tunnel junction. The first magnetic tunnel junction 130 can have a first parallel state resistance R_{P1} in the first parallel state, and can have a first antiparallel state resistance R_{AP1} in the first antiparallel state. The second magnetic tunnel junction 230 can have a second parallel state resistance R_{P2} in the second parallel state, and can have a second antiparallel state resistance R_{AP2} in the second antiparallel state.

As discussed above, the first fixed magnetization direction of the first reference layer 132 and the second fixed magnetization direction of the second reference layer 232 are antiparallel to the hard magnetization direction of the magnetic polarizer layer 120, and thus, the first fixed magnetization direction of the first reference layer 132 and the second fixed magnetization direction of the second reference layer 232 are parallel to each other. While the FIGS. 3A-3D illustrate an upward-pointing hard magnetization direction, it is understood that the hard magnetization direction may point downward in an alternative configuration, and that the magnetization directions of all other magnetic elements flip in the alternative configuration.

The first magnetic tunnel junction 130 has a first parallel state resistance R_{P1} when a magnetization direction of the first free layer 138 is parallel to the first fixed magnetization direction of the first reference layer 132; the second magnetic tunnel junction 230 has a second parallel state resistance R_{P2} when a magnetization direction of the second free layer 238 is parallel to the second fixed magnetization direction of the second reference layer 232; and the second parallel state resistance R_{P2} is different from the first parallel state resistance R_{P1}. While an embodiment is described in which the second parallel state resistance R_{P2} is higher than the first parallel state resistance R_{P1}, alternative embodiments are expressly contemplated herein in which the second parallel state resistance R_{P2} is lower than the first parallel state resistance R_{P1}. In summary, the second parallel state resistance R_{P2} is different than the first parallel state resistance R_{P1} in one embodiment.

In one embodiment, the first magnetic tunnel junction 130 has a first antiparallel state resistance R_{AP1} when the magnetization direction of the first free layer 138 is antiparallel to the first fixed magnetization direction of the first reference layer 132; the second magnetic tunnel junction 230 has a second antiparallel state resistance R_{AP2} when the magnetization direction of the second free layer 238 is antiparallel to the second fixed magnetization direction of the second reference layer 232; and the sum of the first antiparallel state resistance R_{AP} and the second parallel state resistance R_{P2} is different from a sum of the first parallel state resistance R_{P1} and the second antiparallel state resistance R_{AP2}.

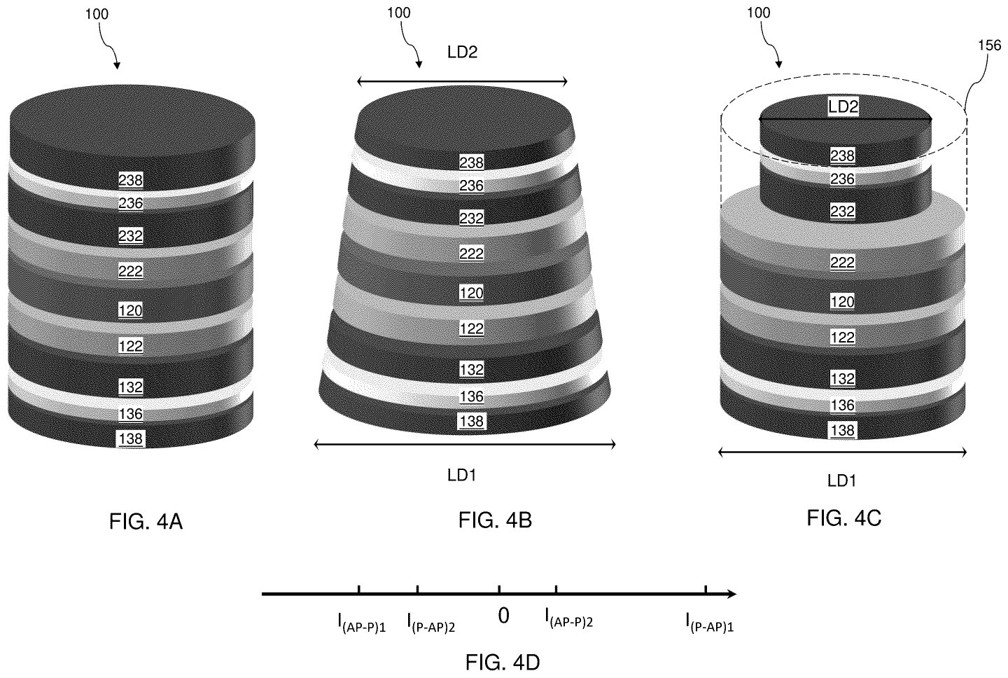

FIGS. 4A-4C are perspective views of various embodiments of the first exemplary magnetoresistive memory cell 100 of the present disclosure. FIG. 4A illustrates an embodiment in which each component within the first exemplary magnetoresistive memory cell 100 has a same area (e.g., horizontal cross-sectional area), but the second free layer 238 has a greater thickness than the first free layer 138. Alternatively, the second free layer 238 may have a lesser thickness than the first free layer 138. Thus, the free layers (138, 238) may have different thicknesses from each other. Alternatively or in addition to the different free layer thickness, the second free layer 238 may have a different damping coefficient value from that of the first free layer 138. The different damping coefficient may be obtained by a different crystalline state of the two free layers (e.g., where one free layer has a more ordered crystalline structure than the other free layer) and/or by a different composition of the free layers (e.g., where the two free layers have a different ratio of alloying elements from each other).

The device of this embodiment can be manufactured by depositing a layer stack of component layers and by patterning the layer stack such that the sidewalls of the patterned portions of the layer stack are formed in a cylindrical vertical plane, and are vertically coincident among one another. As used herein, a first surface and a second surface are vertically coincident if the second surface overlies or underlies the first surface, and are located within a same vertical plane. The lateral dimension (such as a diameter) of the first exemplary magnetoresistive memory cell 100 may be in a range from 10 nm to 40 nm, although lesser and greater lateral dimensions may also be employed.

FIG. 4B illustrates an embodiment in which the sidewalls of the first exemplary magnetoresistive memory cell 100 are formed with finite taper angle. In this case, the bottommost surface of the first exemplary magnetoresistive memory cell 100 (which may be, for example, the bottom surface of the first free layer 138) has a first lateral dimension LD1 and the topmost surface of the first exemplary magnetoresistive memory cell 100 (which may be, for example, the top surface of the second free layer 238) has a second lateral dimension LD2 that is less than the first lateral dimension LD1. In one embodiment, the first free layer 138 has a first lateral dimension LD1 along a horizontal direction, and the second free layer 238 has a second lateral dimension LD2 along the horizontal direction. The second lateral dimension LD2 is less than the first lateral dimension LD1. The taper angle of the sidewall of the first exemplary magnetoresistive memory cell 100 may be greater than 0 degree and less than 30 degrees, and may be in a range from 1 degree to 10 degrees, although lesser and greater taper angles may also be employed. The first lateral dimension LD1 (such as a bottom diameter) of the first exemplary magnetoresistive memory cell 100 may be in a range from 15 nm to 40 nm, although lesser and greater first lateral dimensions may also be employed. The second lateral dimension LD2 (such as a top diameter) of the first exemplary magnetoresistive memory cell 100 may be in a range from 5 nm to 22 nm, although lesser and greater first lateral dimensions may also be employed.

FIG. 4C illustrates an embodiment in which two anisotropic etch processes are employed to pattern the first exemplary magnetoresistive memory cell 100. A first anisotropic etch step can pattern the second magnetic tunnel junction 230, and an optional tubular dielectric spacer 156 can be formed around the second magnetic tunnel junction 230. Subsequently, the first magnetic tunnel junction 130 can be patterned such that the sidewall of components of the first magnetic tunnel junction 130 is vertically coincident with an outer sidewall of the tubular dielectric spacer 156. In this case, the first exemplary magnetoresistive memory cell 100 comprises a tubular dielectric spacer 156 laterally surrounding and contacting the second magnetic tunnel junction 230 and not contacting the first magnetic tunnel junction 130. In one embodiment, the bottommost surface of the first exemplary magnetoresistive memory cell 100 (which may be, for example, the bottom surface of the first free layer 138) has a first lateral dimension LD1 and the topmost surface of the first exemplary magnetoresistive memory cell 100 (which may be, for example, the top surface of the second free layer 238) has a second lateral dimension LD2 that is less than the first lateral dimension LD1. In one embodiment, the first free layer 138 has a first lateral dimension LD1 along a horizontal direction, and the second free layer 238 has a second lateral dimension LD2 along the horizontal direction. The second lateral dimension LD2 is less than the first lateral dimension LD1. The first lateral dimension LD1 (such as a bottom diameter) of the first exemplary magnetoresistive memory cell 100 may be in a range from 15 nm to 40 nm, although lesser and greater first lateral dimensions may also be employed. The second lateral dimension LD2 (such as a top diameter) of the first exemplary magnetoresistive memory cell 100 may be in a range from 5 nm to 22 nm, although lesser and greater first lateral dimensions may also be employed.

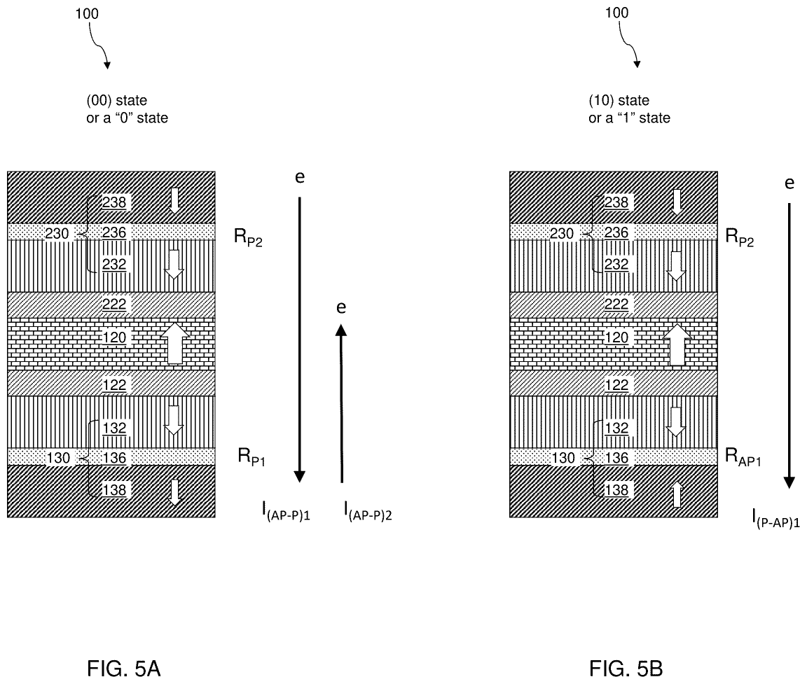

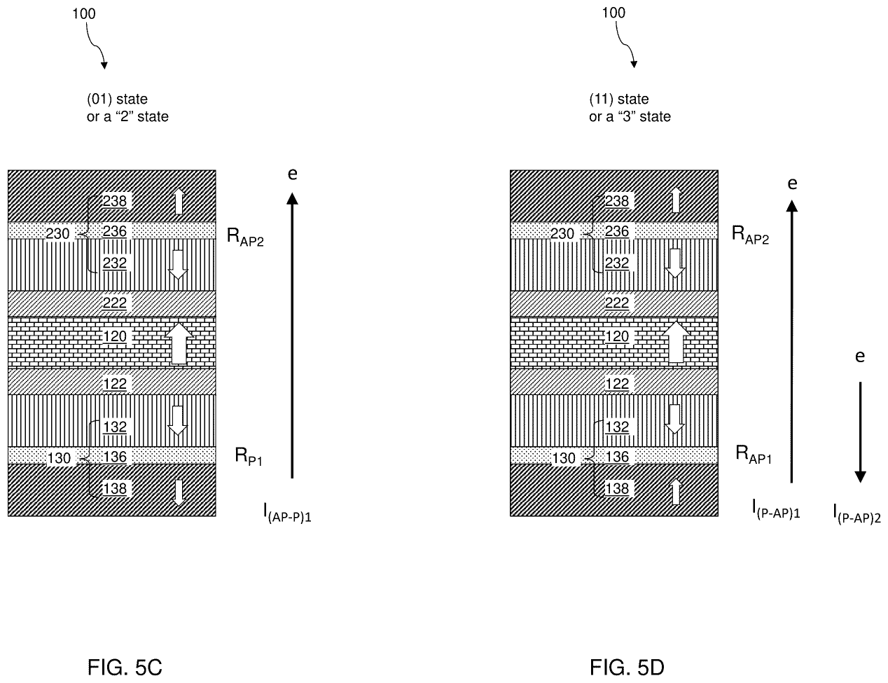

According to as aspect of the present disclosure, the first exemplary magnetoresistive memory cell 100 may be programmed into any of the magnetic configurations (e.g., memory states) illustrated in FIGS. 3A-3D by selecting a suitable programming voltage pulse or pulses, which can be provided by a programming circuit, such as the driver circuits (601, 602). FIG. 4D is a diagram showing the polarity and the relative magnitude of various programming currents that may be used to program the first exemplary magnetoresistive memory cell 100 of the present disclosure. FIGS. 5A-5D are combinations of a schematic vertical cross-sectional view and a schematic diagram illustrating current flow directions and magnitudes of programming current for the first exemplary magnetoresistive memory cell 100 into the various magnetic configurations of the magnetization directions shown in FIGS. 3A-3D.

Generally, the programming circuit can be configured to deterministically program magnetization directions of the first free layer 138 and the second free layer 238 in the magnetoresistive memory cell 100 into any magnetic configuration that is selected from a first magnetic configuration in which the first magnetic tunnel junction 130 is in a first parallel state and the second magnetic tunnel junction 230 is in a second parallel state (as shown in FIGS. 3A and 5A); a second magnetic configuration in which the first magnetic tunnel junction 130 is in a first antiparallel state and the second magnetic tunnel junction 230 is in the second parallel state (as shown in FIGS. 3B and 5B); a third magnetic configuration in which the first magnetic tunnel junction 130 is in the first parallel state and the second magnetic tunnel junction 230 is in a second antiparallel state (as shown in FIGS. 3C and 5C); or a fourth magnetic configuration in which the first magnetic tunnel junction 130 is in the first antiparallel state and the second magnetic tunnel junction 230 is in the second antiparallel state (as shown in FIGS. 3D and 5D).

In one embodiment, the first magnetic configuration, the second magnetic configuration, the third magnetic configuration, and the fourth magnetic configuration provide four different values for a sum of a first tunneling magnetoresistance of the first magnetic tunnel junction 130 and a second tunneling magnetoresistance of the second magnetic tunnel junction 230. Table 1 below shows the normalized simulated values of various magnetoresistance values for four different magnetoresistive memory cells with different free layer thicknesses having the configuration shown in FIG. 4A. In the last cell, the two RA values of the two MTJs (130, 230) are the same, which provides only three resistive memory states or levels per cell instead of four.

TABLE 1

| | | R in kΩ | R in kΩ | R in kΩ | R in kΩ |
|---|---|---|---|---|---|
| | | (eCD = 30 nm | (eCD = 20 nm | (eCD = 15 nm | (eCD = 30 nm |
| | | RA = 10, 5 Ω-μm², | RA = 10, 5 Ω-μm², | RA = 10, 5 Ω-μm², | RA = 10 Ω-μm², |
| | | TMR = 200%) | TMR = 200%) | TMR = 200%) | TMR = 200%) |
| | R_{P1}/R_{AP1}/R_{P2}/R_{AP2} | 14.1/42.4/7.1/21.2 | 31.8/95.5/15.9/47.7 | 56.6/169.8/28.3/84.9 | 14.1/42.4/14.1/42.4 |
| 00 | R_{P1} & R_{P2} | 21.2 | 47.7 | 84.9 | 28.2 |
| 01 | R_{P1} & R_{AP2} | 35.3 (TMR = 66.6%) | 79.5 (TMR = 66.6%) | 141.5 (TMR = 66.6%) | 56.5 (TMR = 100%) |
| 10 | R_{AP1} & R_{P2} | 49.5 (TMR = 133%) | 111.4 (TMR = 133%) | 198.2 (TMR = 133%) | 56.5 (TMR = 100%) |
| 11 | R_{AP1} & R_{AP2} | 63.6 (TMR = 200%) | 143.2 (TMR = 200%) | 254.7 (TMR = 200%) | 84.8 (TMR = 200%) |

Table 2 below shows the normalized simulated values of various magnetoresistance values for four different magnetoresistive memory cells with different free layer areas having the configuration shown in FIG. 4C.

TABLE 2

| | | R in kΩ | R in kΩ | R in kΩ | R in kΩ |
|---|---|---|---|---|---|
| | | (eCD = 20/30 nm | (eCD = 20/25 nm | (eCD = 15/20 nm | (eCD = 12/15 nm |
| | | RA = 10 Ω-μm², | RA = 10 Ω-μm², | RA = 10 Ω-μm², | RA = 10 Ω-μm², |
| | | TMR = 200%) | TMR = 200%) | TMR = 200%) | TMR = 200%) |
| | R_{P1}/R_{AP1}/R_{P2}/R_{AP3} | 31.8/95.5/14.1/42.4 | 31.8/95.5/20.4/61.1 | 56.6/169.8/31.8/95.5 | 88.4/265.3/56.6/169.8 |
| 00 | R_{P1} & R_{P2} | 45.9 | 52.2 | 88.4 | 145 |
| 01 | R_{P2} & R_{AP1} | 74.2 (TMR = 61.7%) | 92.9 (TMR = 78%) | 152.1 (TMR = 72%) | 258.2 (TMR = 78%) |
| 10 | R_{AP2} & R_{P1} | 109.6 (TMR = 139%) | 115.9 (TMR = 122%) | 201.6 (TMR = 128%) | 321.9 (TMR = 122%) |
| 11 | R_{AP1} & R_{AP2} | 137.9 (TMR = 200%) | 156.6 (TMR = 200%) | 265.3 (TMR = 200%) | 435.1 (TMR = 200%) |

Tables 1 and 2 illustrate that it is possible to provide a set of plural (e.g., three or four) resistive states or levels per multi-level memory cell shown in FIGS. 4A and 4C.

Referring to FIG. 5A, the programming of the first exemplary magnetoresistive memory cell 100 into the first (00) magnetic configuration can be achieved by a two-step programming process, in which a relatively large negative (i.e., in downward direction) electron current (I_{(AP-P)1}) is applied to the magnetoresistive memory cell 100. This current switches the first free layer 138 into the parallel state with its respective first reference layer 132. The negative electron current direction flows from the first reference layer 132 to the first free layer 138, i.e., downward. Once the first free layer 138 is in the parallel state, a relatively small positive (i.e., in upward direction) electron current (I_{(AP-P)2}) is applied to the magnetoresistive memory cell 100 in the opposite direction from the second reference layer 232 to the second free layer 238. This current switches the second free layer 238 into the parallel state with its respective second reference layer 232. However, this current will not disturb the first free layer 138 parallel state because the relatively small positive electron current (I_{(AP-P)2}) is smaller than the relatively large positive electron current (I_{(P-AP)1}) required to switch the first free layer 138 to the antiparallel state. Thus, both memory bits (i.e., the first and the second MTJs (130, 230)) are switched to the first (00) state.

Referring to FIG. 5B, the programming of the first exemplary magnetoresistive memory cell 100 into the second (10) magnetic configuration can be achieved by a one-step programming process. The relatively large positive (i.e., in upward direction) electron current (I_{(P-AP)1}) is applied to the magnetoresistive memory cell 100 to switch the first free layer 138 to the antiparallel state. The second free layer 238 will either remain in the parallel state or be switched into the parallel state because the applied relatively large positive electron current (I_{(P-AP)1}) is larger than the relatively small positive electron current (I_{(AP-P)2}) requires switching the second free layer 238 into the parallel state.

Referring to FIG. 5C, the programming of the first exemplary magnetoresistive memory cell 100 into the third (01) magnetic configuration can be achieved by a one-step programming process. A relatively large negative (i.e., downward) electron current (I_{(AP-P)1}) is applied to the magnetoresistive memory cell 100 to switch the first free layer 138 to the parallel state. The second free layer 238 is switched into the antiparallel state because the applied relatively large negative electron current (I_{(AP-P)1}) is larger than the relatively small negative current (I_{(P-AP)2}) required to switch the second free layer 238 into the antiparallel state.

Referring to FIG. 5D, the programming of the first exemplary magnetoresistive memory cell 100 into the fourth (11) magnetic configuration can be achieved by a two-step programming process. The relatively large positive (i.e., upward) electron current (I_{(P-AP)1}) is applied to the magnetoresistive memory cell 100 to switch the first free layer 138 to the antiparallel state. The second free layer 238 is switched into the parallel state because the applied relatively large positive electron current (I_{(P-AP)1}) is larger than the relatively small positive electron current (I_{(AP-P)2}) required to switch the second free layer 238 into the parallel state. Once the first free layer 138 is in the antiparallel state, a relatively small negative (i.e., downward) current (I_{(P-AP)2}) is applied to the magnetoresistive memory cell 100 in the opposite direction to switch the second free layer 238 into the antiparallel state. However, this current will not disturb the first free layer 138 antiparallel state because the relatively small negative current (I_{(P-AP)2}) is smaller than the relatively large negative current (I_{(AP-P)1}) required to switch the first free layer 138 to the parallel state. Thus, both memory bits (i.e., the first and the second MTJs (130, 230)) are switched to the fourth (11) state. In one embodiment, the magnetoresistive memory cells 100 may comprise multi-level spin-transfer torque (STT) memory cells that may store at least three, such as four different memory states.

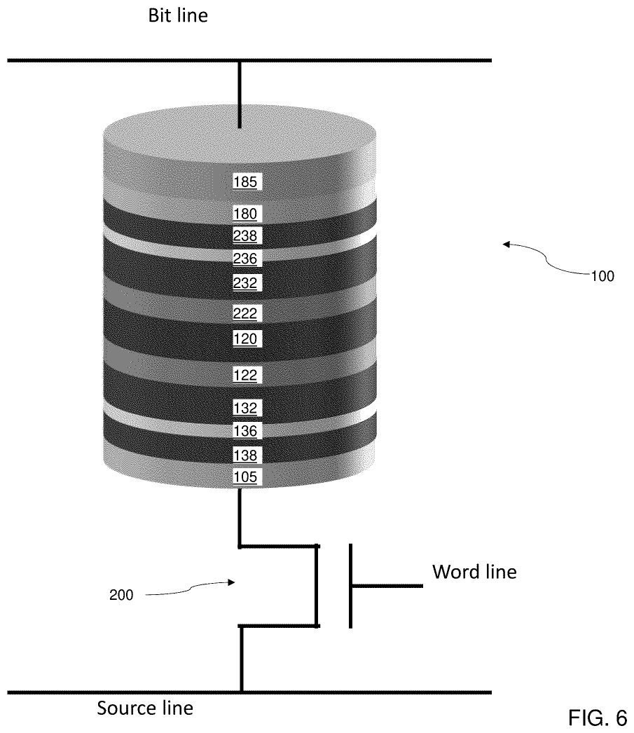

Referring to FIG. 6, a magnetoresistive memory device including a single magnetoresistive memory cell 100 and an access transistor 200 is illustrated according to an embodiment of the present disclosure. The magnetoresistive memory cell 100 may comprise a first electrode 105 (such as a first metal plate) that is electrically connected to the first free layer 138, and a second electrode 185 (such as a second metal plate) that is electrically connected to the second free layer 238. An additional metal plate 180 may be optionally interposed between the second free layer 238 and the second electrode 185. The drain region of the access transistor 200 can be electrically connected to the first electrode 105. The source region of the access transistor 200 can be electrically connected to a source line. The gate electrode of the access transistor 200 can be electrically connected to a word line. The second electrode 185 can be electrically connected to a bit line. In one embodiment, an array, such as a two-dimensional array, of series connections of a magnetoresistive memory cell 100 and an access transistor can be provided.

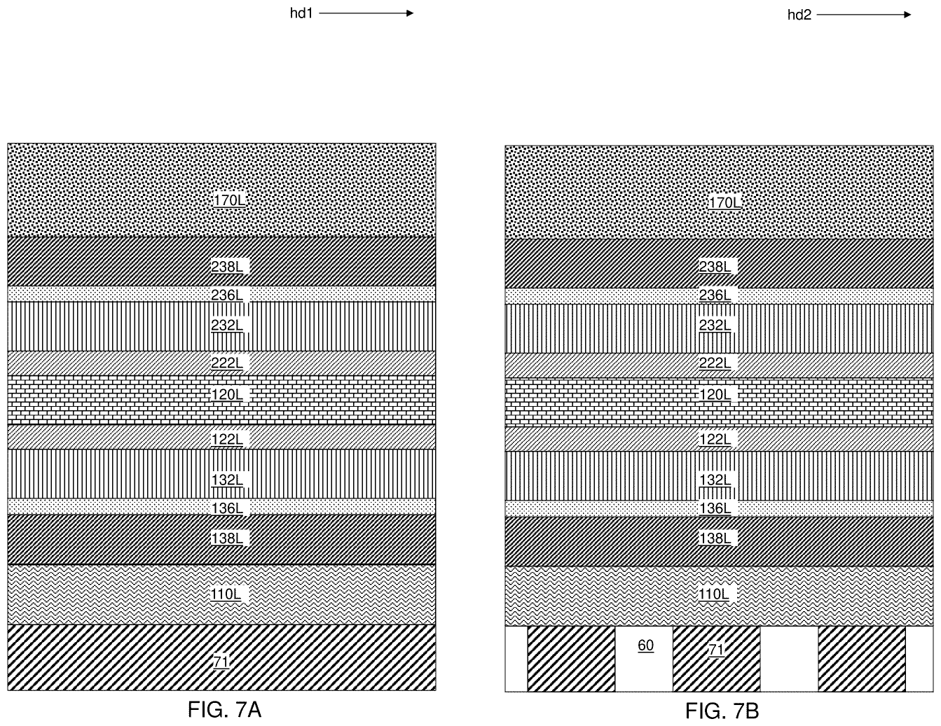

The magnetoresistive memory devices of the present disclosure may be fabricated employing deposition and patterning of various material layers. An optional thermal annealing process may be subsequently conducted to enhance the magnetic properties of the magnetic material layers having fixed magnetization directions. A hardmask material layer can be subsequently formed, and can be patterned into an array of hardmask material portions using a reactive ion etch process. An ion beam etching (IBE) may be employed to pattern the various material layers underlying the hardmask material portions. The magnetoresistive memory cells 100 can be encapsulated with a dielectric material and subsequently planarized to provide a planarized top surface. Exemplary sequences of processing steps that can be employed to manufacture an array of magnetoresistive memory cells are illustrated in FIGS. 7A-10B and 11A-14B.

Referring to FIGS. 7A and 7B, a portion of a first embodiment of a first exemplary structure is illustrated during a processing step employed to form a two-dimensional array of magnetoresistive memory cells. The structure illustrated in FIGS. 7A and 7B can be derived from the exemplary structure illustrated in FIG. 1 by forming a layer stack including an optional selector material layer 110L, a first continuous free layer 138L, a first continuous tunnel barrier layer 136L, a first continuous reference layer 132L, a first continuous antiferromagnetic coupling layer 122L, a continuous magnetic polarizer layer 120L, a second continuous antiferromagnetic coupling layer 222L, a second continuous reference layer 232L, a second continuous tunnel barrier layer 236L, a second continuous free layer 238L, and a hardmask material layer 170L over the first conductive lines 71 and the lower-level dielectric material layers 60. In some embodiments, at least one optional continuous nonmagnetic metal layer (not illustrated) may be provided below the first continuous free layer 138L to form the first electrode. In some embodiments, at least one additional continuous nonmagnetic metal layer (not illustrated) may be provided between the second continuous free layer 238L and the hardmask material layer 170L to form the additional metal plate 180.

The selector material layer 110L may comprise any suitable non-Ohmic switching material. In one embodiment, the selector material layer 110L may comprise an ovonic threshold switch (OTS) material. The thickness of the selector material layer 110L may be in a range from 5 nm to 50 nm, such as from 10 nm to 30 nm, although lesser and greater thicknesses may also be employed. Suitable barrier material layers (such as nonmagnetic metal or metal nitride layers or a carbon (e.g., graphene) layers) may be optionally disposed between the selector material layer 110L and the first continuous free layer 138L, and between the selector material layer 110L and the first conductive lines 71.

Each of the first continuous free layer 138L, the first continuous tunnel barrier layer 136L, the first continuous reference layer 132L, the first continuous antiferromagnetic coupling layer 122L, the continuous magnetic polarizer layer 120L, the second continuous antiferromagnetic coupling layer 222L, the second continuous reference layer 232L, the second continuous tunnel barrier layer 236L, and the second continuous free layer 238L may comprise a respective suitable material and may have a respective suitable thickness for subsequently providing the stack of a first free layer 138, a first tunnel barrier layer 136, a first reference layer 132, a first antiferromagnetic coupling layer 122, a magnetic polarizer layer 120, a second antiferromagnetic coupling layer 222, a second reference layer 232, a second tunnel barrier layer 236, and a second free layer 238 as described with reference to FIG. 2.

The hardmask material layer 170L includes a material that can function as an etch mask material for the layer stack (110L, 138L, 136L, 132L, 122L, 120L, 222L, 232L, 236L, 238L) during a subsequent etch process. For example, the hardmask material layer 170L may comprise a metallic material (such as TiN, TaN, WN, MON, W, Ti, Ta, Mo, etc.) or a carbon-based ashable etch mask material, such as diamond-like carbon (DLC) or amorphous carbon. The thickness of the hardmask material layer 170L may range from 40 nm to 300 nm, although lesser and greater thicknesses may also be employed. The hardmask material layer 170L can be deposited using physical vapor deposition or chemical vapor deposition (CVD). In one embodiment, the hardmask material layer 170L may comprise and/or may consist essentially of diamond-like carbon. The use of diamond-like carbon as a hard mask material provides a high ion milling resistance, and thus, allows for the fabrication of denser MRAM arrays with minimized shadowing effects.

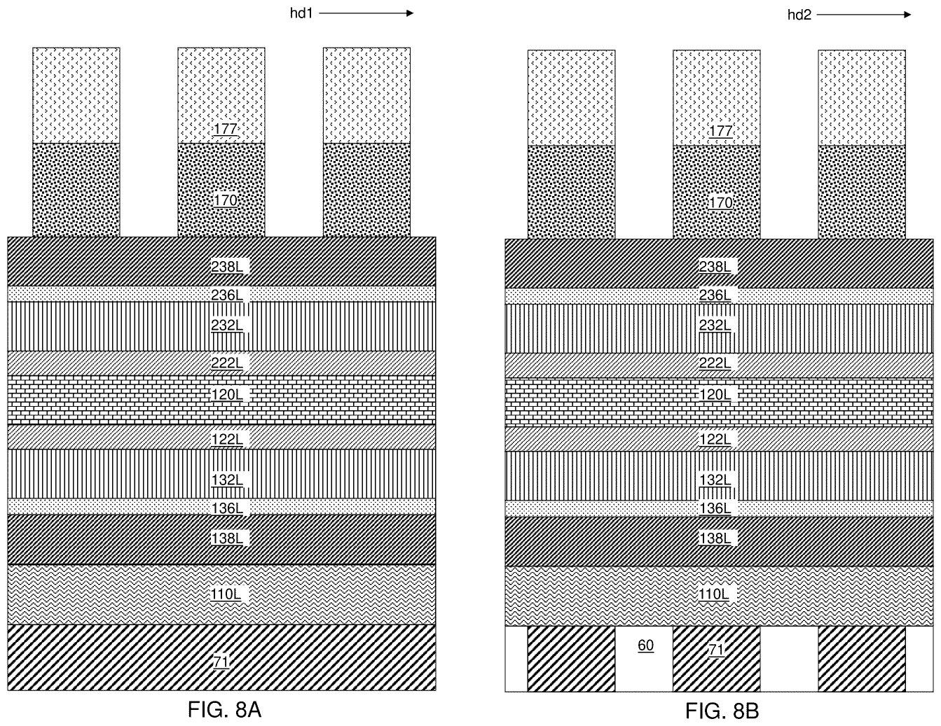

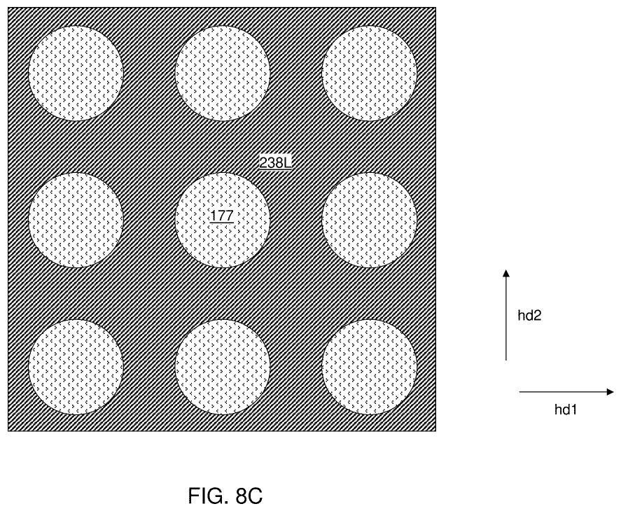

Referring to FIGS. 8A-8C, a photoresist layer can be applied over the hardmask material layer 170L, and can be lithographically patterned into a two-dimensional array of discrete photoresist material portions 177. An anisotropic etch process can be performed to transfer the pattern in the two-dimensional array of discrete photoresist material portions 177 through the hardmask material layer 170L. The hardmask material layer 170L is patterned into a two-dimensional array of patterned hardmask portions 170. The two-dimensional array of discrete photoresist material portions 177 can be subsequently removed, for example, by ashing.

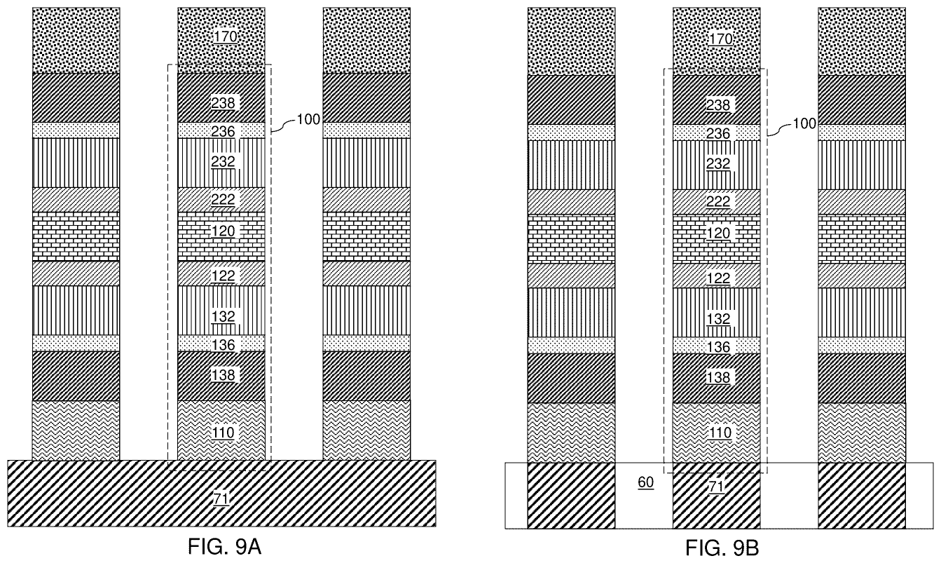

Referring to FIGS. 9A and 9B, an anisotropic etch process can be performed to transfer the pattern in the two-dimensional array of patterned hardmask portions 170 through the layer stack (110L, 138L, 136L, 132L, 122L, 120L, 222L, 232L, 236L, 238L). The anisotropic etch process may comprise an ion beam etch (IBE) process and/or a reactive ion etch process. The two-dimensional array of patterned hardmask portions 170 can be employed as an etch mask during the anisotropic etch process. The anisotropic etch process may stop on the first conductive lines 71. A two-dimensional array of magnetoresistive memory cells 100 can be formed. Each magnetoresistive memory cell 100 may have an upper portion having the same structure as the structure illustrated in FIG. 4A (if the sidewalls of the magnetoresistive memory cells 100 are vertical) or as the structure illustrated in FIG. 4B (if the sidewalls of the magnetoresistive memory cells 100 are tapered), and may have a lower portion including the optional selector element 110.

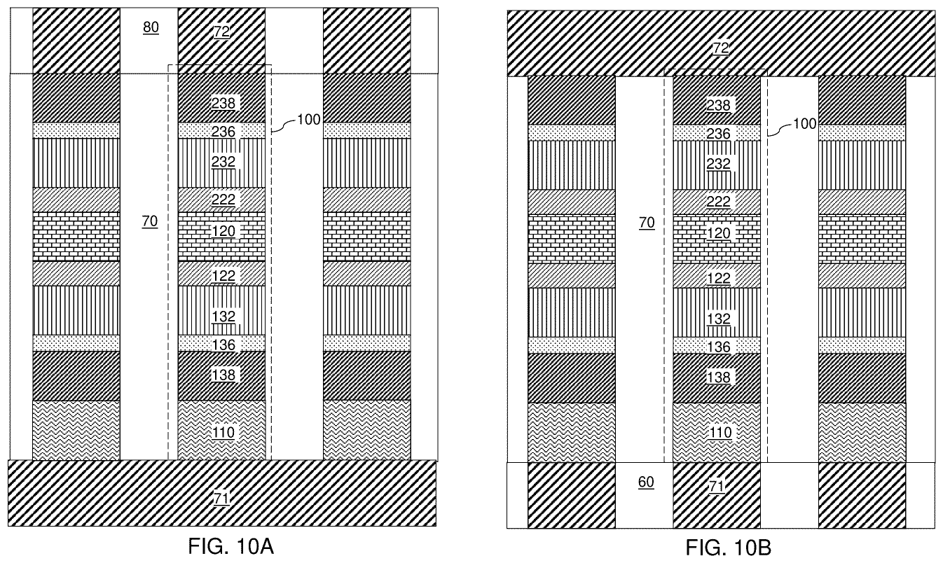

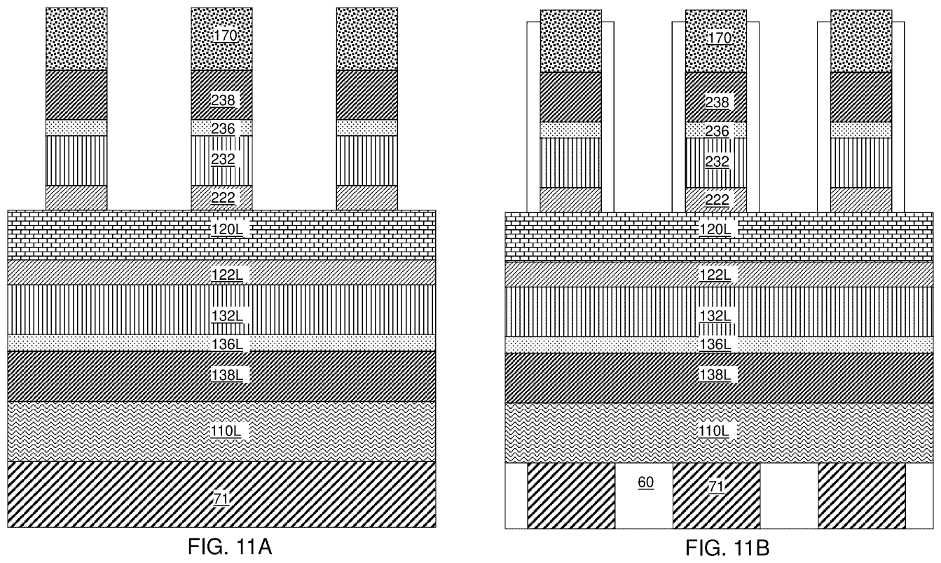

Referring to FIGS. 10A and 10B, a dielectric fill material such as undoped silicate glass (i.e., silicon oxide) or a doped silicate glass can be deposited around the two-dimensional array of magnetoresistive memory cells 100, and can be subsequently planarized to form a dielectric matrix layer 70. The two-dimensional array of patterned hardmask portions 170 may be removed prior to, during or after formation of the dielectric matrix layer 70. In one embodiment, the top surface of the dielectric matrix layer 70 may be formed at or above the horizontal plane including the top surfaces of the second free layers 238.

Upper-level dielectric material layers 80 embedding the second electrode 185 and upper-level metal interconnect structures can be formed over the two-dimensional array of magnetoresistive memory cells 100 and the dielectric matrix layer 70. The upper-level dielectric material layers 80 may comprise a bottommost dielectric material layer, which is herein referred to as a second dielectric material layer. Second conductive lines 72 can be formed within the second dielectric material layer. In one embodiment, the first conductive lines 71 may laterally extend along the first horizontal direction hd1 and the second conductive lines 72 may laterally extend along the second horizontal direction hd2. In one embodiment, the second horizontal direction hd2 may be perpendicular to the first horizontal direction hd1. In one embodiment, each first conductive line 71 may contact bottom surfaces of a respective row of magnetoresistive memory cells 100, and each second conductive line 72 may contact top surfaces of a respective column of magnetoresistive memory cells 100.

The magnetoresistive memory device comprises first conductive lines 71 laterally extending along a first horizontal direction hd1 and electrically connected to the first free layers 138 within the two-dimensional array of magnetoresistive memory cells 100, and second conductive lines 72 laterally extending along a second horizontal direction hd2 and electrically connected to the second free layers 238 within the two-dimensional array of magnetoresistive memory cells 100.

The magnetoresistive memory cell 100 may comprise an optional selector element 110 located under the first free layer 138 or over the second free layer 238 and providing non-Ohmic resistive characteristics such that the selector element 110 allows conduction of electrical current therethrough only when a voltage difference across the selector element 110 has a magnitude that is greater than a threshold voltage magnitude. In one embodiment, the magnetoresistive memory cell 100 may comprise a selector element 110 in a series connection with the first magnetitic tunnel junction 130 and the second magnetic tunnel junction 230; and the magnetoresistive memory device comprises word line drivers configured to drive one set of conductive lines selected from the first conductive lines 71 or the second conductive lines 72, and bit line drivers configured to drive another set of conductive lines selected from the first conductive lines 71 or the second conductive lines 72. The word line drivers and the bit line drivers may be comprise driver circuits (601, 602) described with reference to FIG. 1.

Referring to FIGS. 11A and 11B, a region of a second embodiment of the first exemplary structure is illustrated after patterning the second continuous free layer 238L, the second continuous tunnel barrier layer 236L, the second continuous reference layer 232L, and the second continuous antiferromagnetic coupling layer 222L. The second embodiment of the first exemplary structure can be derived from the first embodiment of the first exemplary structure illustrated in FIGS. 8A and 8B by performing a first anisotropic etch process that transfers the pattern of the patterned hardmask portions 170 through the second continuous free layer 238L, the second continuous tunnel barrier layer 236L, the second continuous reference layer 232L, and the second continuous antiferromagnetic coupling layer 222L without etching through the continuous magnetic polarizer layer 120L. The first anisotropic etch process may comprise an ion beam etch (IBE) process and/or a reactive ion etch process. A two-dimensional array of pillar structures (222, 232, 236, 238, 170) can be formed over the continuous magnetic polarizer layer 120L. Each pillar structure (222, 232, 236, 238, 170) may comprise a second antiferromagnetic coupling layer 222, a second reference layer 232, a second tunnel barrier layer 236, a second free layer 238, and a patterned hardmask portion 170.

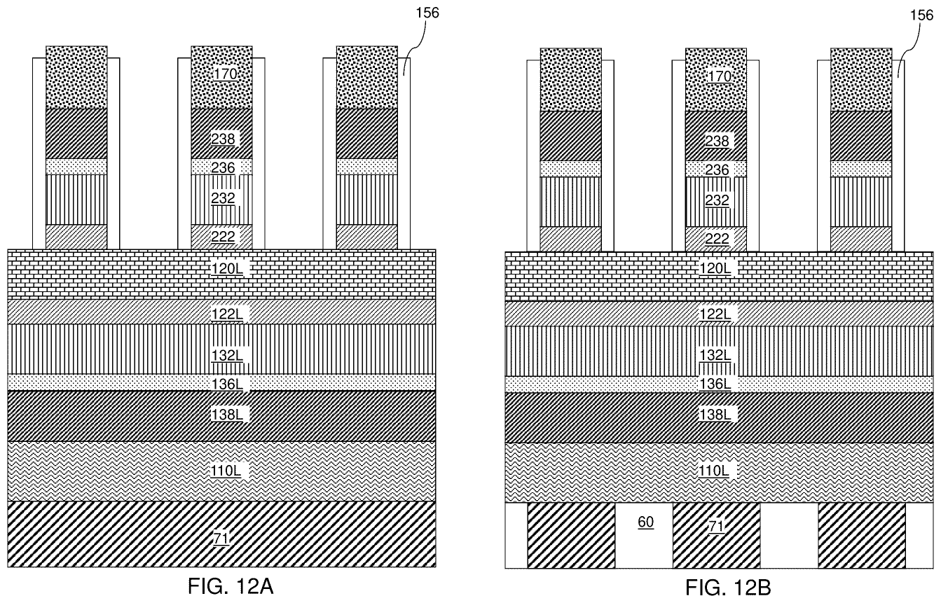

Referring to FIGS. 12A and 12B, a dielectric material liner can be conformally deposited on the physically exposed surfaces of the pillar structures (222, 232, 236, 238, 170). The dielectric material liner comprises a dielectric material, such as silicon oxide, silicon nitride, silicon carbonitride, silicon oxynitride, etc. An anisotropic sidewall spacer etch process can be performed to remove horizontally-extending portions of the dielectric material layer. Remaining portions of the dielectric material liner comprises a two-dimensional array of tubular dielectric spacers 156.

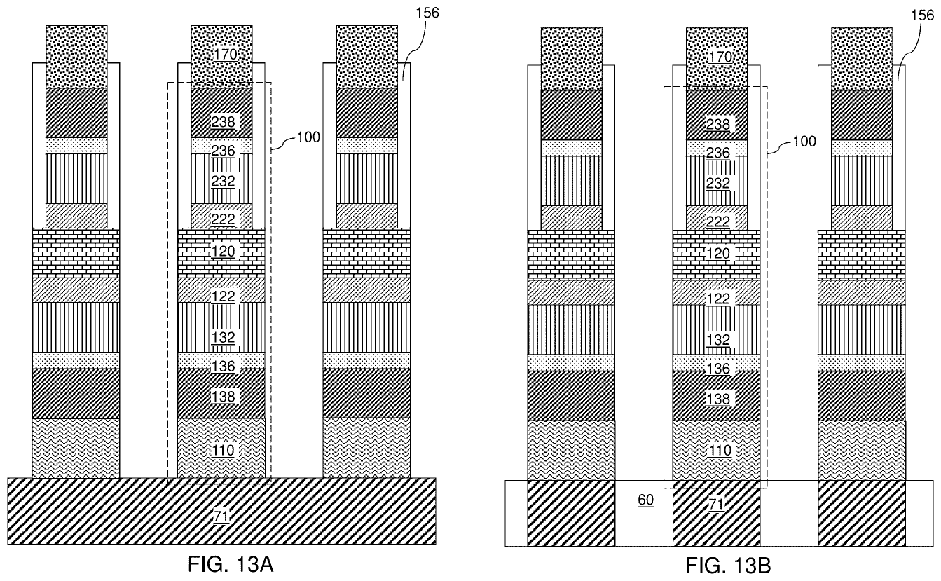

Referring to FIGS. 13A and 13B, a second anisotropic etch process can be performed to transfer the pattern in the two-dimensional array of pillar structures (222, 232, 236, 238, 170) and the respective tubular dielectric spacers 156 through an underlying layer stack (110L, 138L, 136L, 132L, 122L, 120L). The second anisotropic etch process may comprise an ion beam etch (IBE) process and/or a reactive ion etch process. The two-dimensional array of patterned hardmask portions 170 and the two-dimensional array of tubular dielectric spacers 156 can be employed as an etch mask during the second anisotropic etch process. The second anisotropic etch process may stop on the first conductive lines 71. A two-dimensional array of magnetoresistive memory cells 100 can be formed. Each magnetoresistive memory cell 100 may have an upper portion having the same structure as the structure illustrated in FIG. 4C, and may have a lower portion including a selector element 110.

In this case, each first free layer 138 may have a first lateral dimension along a horizontal direction; and each second free layer 238 may have a second lateral dimension along the horizontal direction which is less than the first lateral dimension. In other words, the second free layer 238 has a smaller horizontal area than the first free layer 138. Each the magnetoresistive memory cell 100 may comprise a tubular dielectric spacer 156 laterally surrounding and contacting the second magnetic tunnel junction 230, and not contacting or surrounding the first magnetic tunnel junction 130.

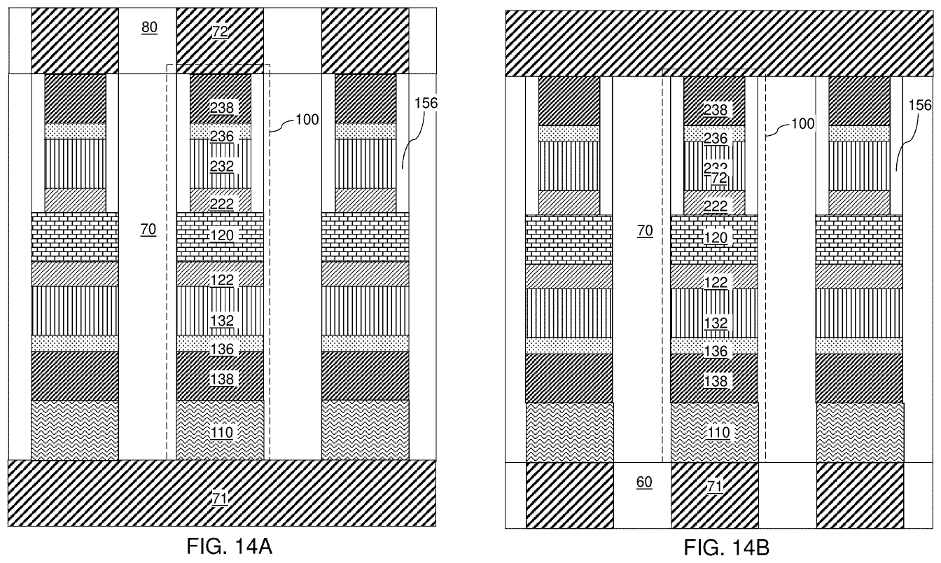

Referring to FIGS. 14A and 14B, the processing steps described with reference to FIGS. 10A and 10B can be performed to form a dielectric matrix layer 70, second conductive lines 72, and upper-level dielectric material layers 80.

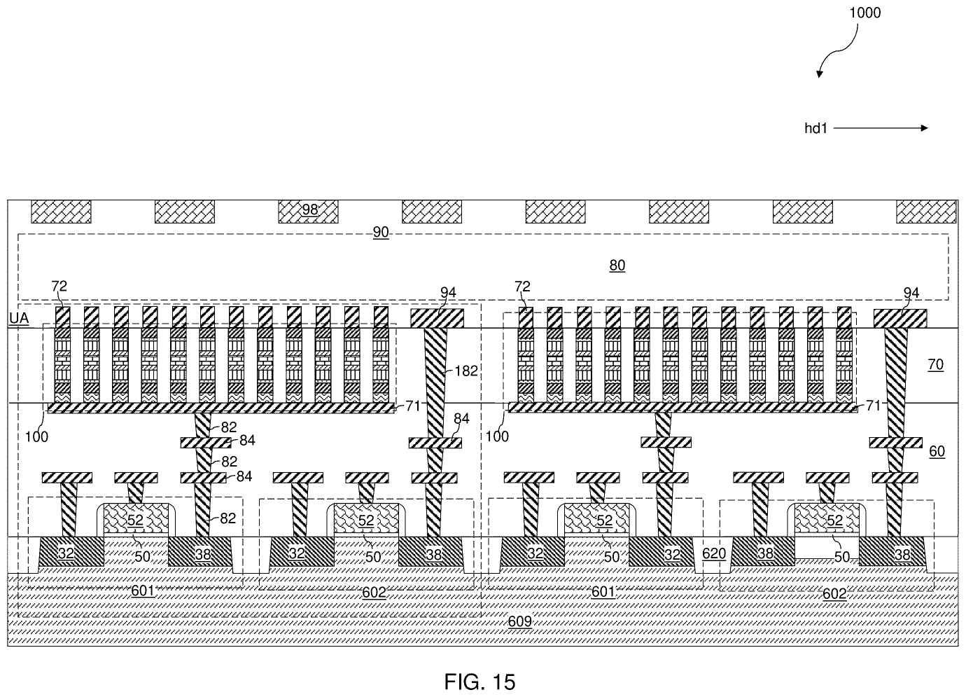

Referring to FIG. 15, additional metal via structures 182 may be formed through the dielectric matrix layer 70 and the lower-level dielectric material layers 60 on a respective one of the lower-level metal interconnect structures (82, 84). Additional conductive lines 94, which are a subset of the upper-level metal interconnect structures 90, can be formed within the second dielectric material layer directly on a top surface of a respective one of the additional metal via structures 182 embedded within the dielectric matrix layer 70. The upper-level dielectric material layers 80 may comprise additional dielectric material layers, which may include via-level dielectric material layers line-level dielectric material layers. The upper-level metal interconnect structures 90 may comprise additional metal via structures (not shown) and additional conductive line structures (not shown). Metallic contact pads 98 may be formed at the topmost level of the upper-level dielectric material layers 80.

Referring collectively to FIGS. 1-15 and according to various embodiments of the present disclosure, a magnetoresistive memory cell 100 includes a magnetic polarizer layer 120 having a hard magnetization along a hard magnetization direction, a first magnetic tunnel junction 130 located on a first (e.g., lower) side of the magnetic polarizer layer 120 and including a first reference layer 132 having a first (e.g., upper) side facing the magnetic polarizer layer 120, a first free layer 138 facing a second (e.g., lower) side of the first reference layer 132, and a first tunnel barrier layer 136 located between the first free layer 138 and the first reference layer 132. The memory cell 100 also includes a second magnetic tunnel junction 230 located on a second (e.g., upper) side of the magnetic polarizer layer 120 and including a second reference layer 232 having a second (e.g., lower) side facing the magnetic polarizer layer 120, a second free layer 238 facing a first (e.g., upper) side of the second reference layer 232, and a second tunnel barrier layer 236 located between the second free layer 238 and the second reference layer 232.

A method of forming a magnetoresistive memory device of the first embodiment includes forming a layer stack comprising, in order from bottom to top, a first continuous free layer 138L, a first continuous tunnel barrier layer 136L, a first continuous reference layer 132L, a continuous magnetic polarizer layer 120L, a second continuous reference layer 232L, a second continuous tunnel barrier layer 236L, and a second continuous free layer 238L. The method also comprises patterning the second continuous free layer 238L, the second continuous tunnel barrier layer 236L, and the second continuous reference layer 232L into first pillar structures comprising second magnetic tunnel junctions 230 and forming tubular dielectric spacers 156 around the first pillar structures. The method further comprises patterning the first continuous free layer 138L, the first continuous tunnel barrier layer 136L, the first continuous reference layer 132L, the continuous magnetic polarizer layer 120L using the first pillar structures and the tubular dielectric spacers 156 to form first magnetic tunnel junctions 130 having a smaller horizontal area than the second tunnel junctions 230.

In addition, a method of operating the magnetoresistive memory cell 100 of the first embodiment includes programming the magnetoresistive memory cell 100 into three or four different memory states. In one embodiment, the step of the programming the magnetoresistive memory cell 100 into three or four different memory states comprises the four memory states selected from a first memory state in which the first magnetic tunnel junction 130 is in a first parallel state and the second magnetic tunnel junction 230 is in a second parallel state; a second memory state in which the first magnetic tunnel junction is in a first antiparallel state and the second magnetic tunnel junction is in the second parallel state; a third memory state in which the first magnetic tunnel junction is in the first parallel state and the second magnetic tunnel junction is in a second antiparallel state; or a fourth memory state in which the first magnetic tunnel junction is in the first antiparallel state and the second magnetic tunnel junction is in the second antiparallel state.

The programming method includes programing the magnetization directions of the first free layer 138 and the second free layer 238 into the first magnetic configuration by applying a relatively large first negative electron current to the magnetoresistive memory cell 100 that flows in a first direction from the first reference layer 132 to the first free layer 138, to switch the first magnetic tunnel junction 130 into the first parallel state; and applying a relatively small first positive electron current to the magnetoresistive memory cell 100 that flows in a second direction from the second reference layer 232 to the second free layer 238, which is opposite to the first direction, to switch the second magnetic tunnel junction 230 into the second parallel state without disturbing the magnetization direction of the first free layer 138 which requires a relatively large second positive electron current which is greater than the first positive electron current to switch into the first antiparallel state.

The programming method also includes programing the magnetization directions of the first free layer and the second free layer into the second magnetic configuration by applying the relatively large second positive electron current to the magnetoresistive memory cell to switch the first magnetic tunnel junction to the first antiparallel state. The programming method also includes programing the magnetization directions of the first free layer and the second free layer into the third magnetic configuration by applying the relatively large first negative electron current to the magnetoresistive memory cell to switch the first magnetic tunnel junction to the first parallel state and to switch the second magnetic tunnel junction into the second antiparallel state.

The programming method also includes programing the magnetization directions of the first free layer and the second free layer into the fourth magnetic configuration by applying the relatively large second positive electron current to the magnetoresistive memory cell to switch the first magnetic tunnel junction into the first antiparallel state and to switch the second magnetic tunnel junction into the second parallel state; and applying a relatively small second negative current which is smaller than the first negative current to the magnetoresistive memory cell to switch the second magnetic tunnel junction into the second antiparallel state, without disturbing the magnetization direction of the first free layer which requires the relatively large first negative current which is greater than the second negative current to switch into the first parallel state.

According to a second embodiment of the present disclosure, the dual free layer a magnetoresistive memory cell may be configured as a single level (i.e., two memory state) memory cell which has improved read signal strength and shorter read (i.e., sense) time than a conventional one free layer STT MRAM memory cell.

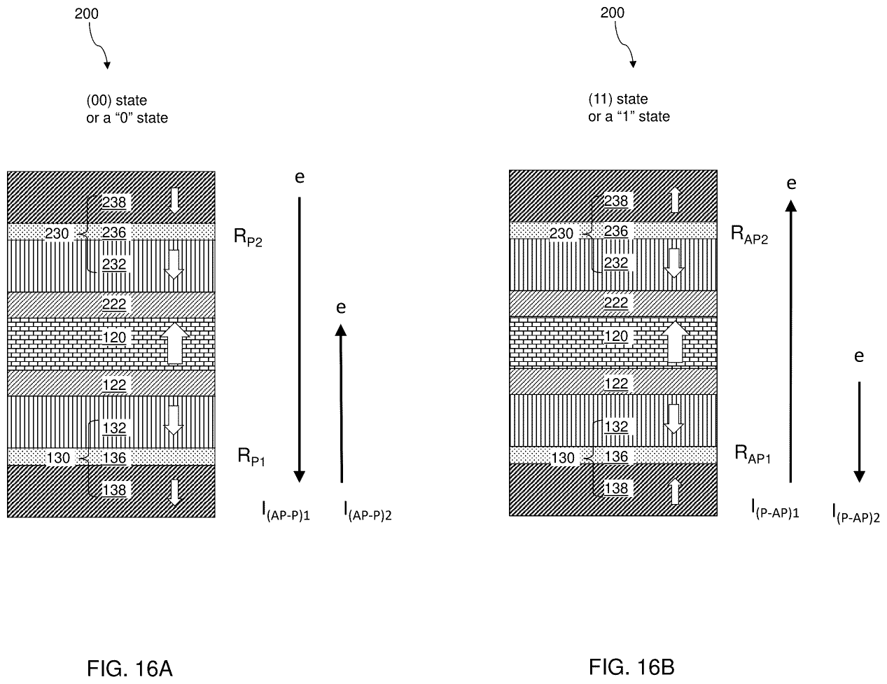

Referring to FIGS. 16A and 16B, a second exemplary magnetoresistive memory cell 200 according to the second embodiment is illustrated in a first magnetic configuration and a second magnetic configuration, respectively. Magnetization directions of various magnetic elements and schematic diagrams illustrating electron flow directions and magnitudes of electrical current for programming are also illustrated.

The second exemplary magnetoresistive memory cell 200 of the second embodiment can be derived from any of the first exemplary magnetoresistive memory cells 100 described with reference to FIGS. 1-15. In one configuration of the second exemplary magnetoresistive memory cell 200, the first and second tunnel barrier layers are the same, and the first and the second free layers are the same. In this configuration, the first tunnel barrier layer 136 and the second tunnel barrier layer 236 may have the same resistance and the same tunneling magnetoresistance, and the first free layer 138 has the same area in a horizontal plane (i.e., the same horizontal cross sectional area, for example the same critical diameter), the same thickness and the same damping coefficient as the second free layer 238 to provide a single level (i.e., two memory state) STT MRAM cell 200. Alternatively, the first free layer 136 may be different from the second free layer 238 in at least one of horizontal area, thickness and/or damping coefficient.

According to an aspect of the present disclosure, the second exemplary magnetoresistive memory cell 200 can be operated such that a magnetic configuration that is equivalent to the first magnetic configuration (i.e., the “00” or “0” memory state) described with reference to FIGS. 3A and 5A and another magnetic configuration (i.e., the “11” or “1” memory state that is equivalent to the fourth magnetic configuration described with reference to FIGS. 3D and 5D are employed as data storage configurations (i.e., memory states).

Referring to FIG. 16A, the two programming currents (I_{(AP-P)1}) and (I_{(AP-P)2}) described with reference to FIG. 5A above may be applied to the second exemplary magnetoresistive memory cell 200, such that the initial relatively large negative programming current (I_{(AP-P)1}) sets the first free layer 138 magnetization direction parallel to the first reference layer 132 magnetization direction, and the subsequent relatively small positive programming current (I_{(AP-P)2}) sets the second free layer 238 magnetization direction parallel to the second reference layer 232 magnetization direction. This places both magnetic tunnel junctions (130, 230) in the low resistance, parallel “0” state.

Referring to FIG. 16B, the two programming currents (I_{(P-AP)1}) and (I_{(P-AP)2}) described with reference to FIG. 5D above may be applied to the second exemplary magnetoresistive memory cell 200, such that the initial relatively large positive programming current (I_{(P-AP)1}) sets the first free layer 138 magnetization direction antiparallel to the first reference layer 132 magnetization direction, and the subsequent relatively small negative programming current (I_{(P-AP)2}) sets the second free layer 238 magnetization direction antiparallel to the second reference layer 232 magnetization direction. This places both magnetic tunnel junctions (130, 230) in the high resistance, antiparallel “1” state.

A resistance difference (AR) is the difference in resistance between two magnetic configurations (i.e., the parallel “0” memory state and the antiparallel “1” memory state) of the second exemplary magnetoresistive memory cell 200. For a conventional spin-transfer torque magnetic random access memory (STT-MRAM) cell containing a single magnetic tunnel junction, the resistance difference is represented by the difference in the electrical resistance between a parallel magnetic configuration and an antiparallel magnetic configuration of the single magnetic tunnel junction within the magnetoresistive memory cell. In other words, resistance difference (ΔR) is given by R_{AP}−R_{P}, where R_{AP} is the tunneling resistance in the antiparallel magnetic configuration (i.e., the “1” memory state), and R_{P} is the tunneling resistance in the parallel magnetic configuration (i.e., the “0” memory state). However, since the second exemplary magnetoresistive memory cell 200 contains two magnetic tunnel junctions (130, 230), the resistance difference (ΔR) is doubled (i.e., (ΔR)=2(R_{AP}−R_{P}) if the first magnetic tunnel junction 130 is the same as the second magnetic tunnel junction 230.

A second parameter is a read voltage difference (ΔVrd) which denotes the variation in the read voltage across a magnetoresistive memory cell corresponding to the resistance difference under a given read current, I_rd (i.e., bias current). The read voltage difference is proportional to a product of the resistance difference and the read current. If the first magnetic tunnel junction 130 is the same as the second magnetic tunnel junction 230, then ΔVrd=ΔR×I_rd. Since the second exemplary magnetoresistive memory cell 200 contains two magnetic tunnel junctions (130, 230), the read voltage difference (ΔVrd) for the same read current for the second exemplary magnetoresistive memory cell 200 is also doubled relative to single magnetic tunnel junction STT MRAM cell, due to the doubling of the resistance difference (ΔR).

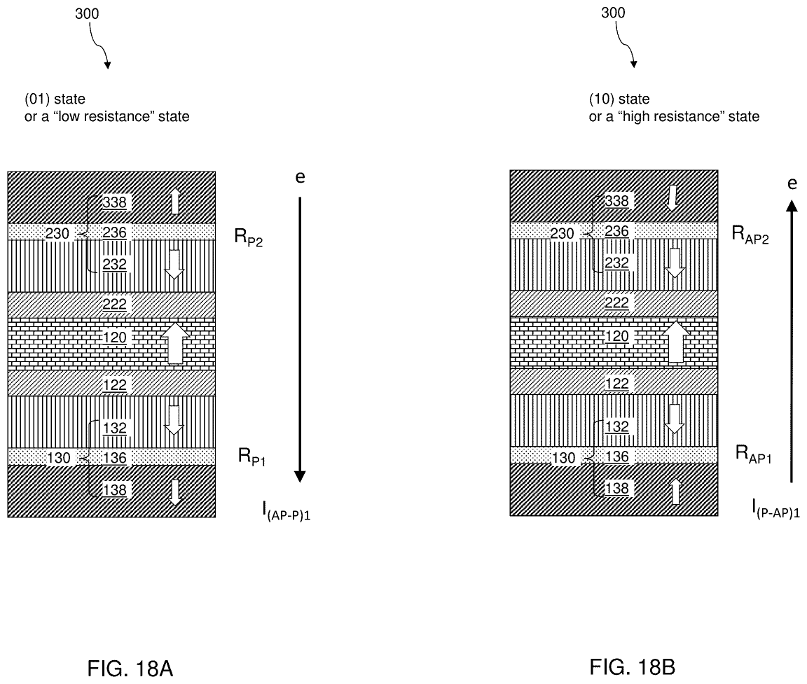

Referring to FIGS. 18A and 18B, a third exemplary magnetoresistive memory cell 300 according to the third embodiment is illustrated in a first magnetic configuration and a second magnetic configuration, respectively. Magnetization directions of various magnetic elements and schematic diagrams illustrating electron flow directions and magnitudes of electrical current for programming are also illustrated. The third exemplary magnetoresistive memory cell 300 of the third embodiment can be derived from the second exemplary magnetoresistive memory cell 200 of the second embodiment by replacing one of the free layer positive spin polarization material with a negative spin polarization material.

In the configuration shown in FIGS. 18A and 18B, the first free layer 138 comprises positive spin polarization material (e.g., a ferromagnetic material such as CoFeB having a positive spin polarization), while the second free layer 338 comprises a negative spin polarization material. In an alternative configuration, the first free layer may comprise the negative spin polarization material, while the second free layer may comprise the positive spin polarization material.

Positive spin polarization refers to a phenomenon in which the spin direction of electrons passing through a magnetic material aligns with the direction of magnetization of the magnetic material. In other words, the magnetization direction is parallel to the direction of the spin polarized current. A magnetic material that provides positive spin polarization is herein referred to as a positive spin polarization material. Positive spin polarization occurs in most ferromagnetic materials. In contrast, negative spin polarization refers to a phenomenon in which the spin direction of electrons passing through a magnetic material aligns along the opposite direction of the direction of magnetization of the magnetic material. In other words, the magnetization direction is antiparallel (i.e., opposite) to the direction of the spin polarized current. A magnetic material that provides negative spin polarization is herein referred to as a negative spin polarization material. Examples of positive spin polarization materials include iron, cobalt, nickel, and their alloys (e.g., CoFe, CoFeB, NiFe, etc). Examples of negative spin polarization materials include disordered body centered cubic FeCr alloys (e.g., Fe₁₋ₓCrₓ with the x value of below 0.7), Mn₂VGa Heusler alloys, Fe₄N and SrRuO₃.

For a magnetic tunnel junction containing a negative spin polarization material free layer, the low resistance state is the antiparallel state in which the magnetization directions of the free and reference layers are antiparallel, and the high resistance state is the parallel state in which the magnetization directions of the free and reference layers are parallel. In contrast, a magnetic tunnel junction containing a positive spin polarization material free layer, the low resistance state is the parallel state in the which the magnetization directions of the free and reference layers are parallel, and the high resistance state is the antiparallel state in which the magnetization directions of the free and reference layers are antiparallel. Therefore, by pairing a magnetic tunnel junction having a positive spin polarization material free layer with a magnetic tunnel junction having a negative spin polarization material free layer, a single programming pulse can be used to program such dual magnetic tunnel junction STT MRAM cell into both the high and low resistance states.

Referring to FIG. 18A, a negative programming current (I_{(AP-P)1}) applied to the STT MRAM cell 300 sets the first free layer 138 magnetization direction parallel to the first reference layer 132 magnetization direction, and sets the second free layer 338 magnetization direction antiparallel to the second reference layer 232 magnetization direction. This places both magnetic tunnel junctions (130, 230) in the low resistance, “01” state.

Referring to FIG. 18B, the positive programming current (I_{(P-AP)1}) sets the first free layer 138 magnetization direction antiparallel to the first reference layer 132 magnetization direction, and sets the second free layer 338 magnetization direction parallel to the second reference layer 232 magnetization direction. This places both magnetic tunnel junctions (130, 230) in the high resistance, “10” state. Thus, a respective single polarity programming current can set the STT MRAM cell 300 into the low and high resistance states.

Generally, all embodiments of the second exemplary magnetoresistive memory cell 200 can be converted into a respective embodiment of the third exemplary magnetoresistive memory cell 300 through substitution of a negative spin polarization material for the positive spin polarization material of one of the free layers (e.g., the second free layer).

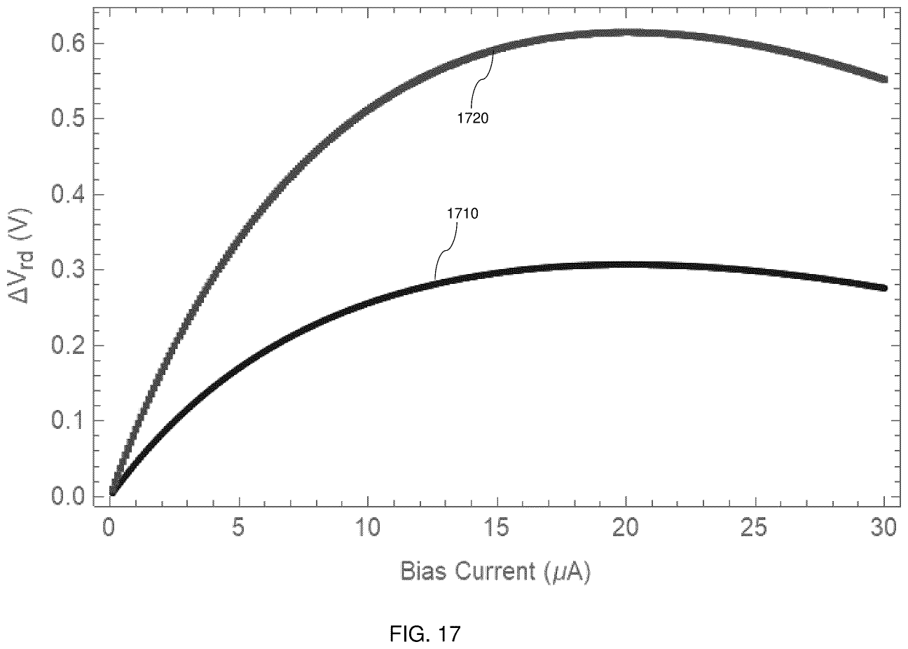

Referring collectively to FIGS. 16A-18B and according to the second and third embodiments of the present disclosure, the first magnetic tunnel junction 130 has a first parallel state resistance when a magnetization direction of the first free layer 138 is parallel to the first fixed magnetization direction described above; and the second magnetic tunnel junction 230 has a second parallel state resistance when a magnetization direction of the second free layer (238, 338) is parallel to the second fixed magnetization direction described above.

In the magnetoresistive memory cell 200 of the second embodiment, the first free layer 138 and the second free layer 238 both comprise a positive spin polarization material. The above described programming circuit is configured to program magnetization directions of the first free layer 138 and the second free layer 238 into two magnetic configurations comprising a first, relatively low resistance magnetic configuration (e.g., “00” or “0” configuration) in which the first magnetic tunnel junction 130 is in the first parallel state and the second magnetic tunnel junction 230 is in the second parallel state; and a second, relatively high resistance magnetic configuration (e.g., “11” or “1” configuration) in which the first magnetic tunnel junction 130 is in the first antiparallel state and the second magnetic tunnel junction 230 is in the second antiparallel state, wherein the relatively high resistance is higher than the relatively low resistance.

In the second embodiment, the programing circuit is configured to program the magnetization directions of the first free layer and the second free layer into the first, relatively low resistance magnetic configuration by applying a relatively large first negative electron current to the magnetoresistive memory cell that flows in a first direction from the first reference layer to the first free layer, to switch the first magnetic tunnel junction into the first parallel state; and applying a relatively small first positive electron current to the magnetoresistive memory cell that flows in a second direction from the second reference layer to the second free layer, which is opposite to the first direction, to switch the second magnetic tunnel junction into the second parallel state without disturbing the magnetization direction of the first free layer which requires a relatively large second positive electron current which is greater than the first positive electron current to switch into the first antiparallel state.

In the second embodiment, the programing circuit is configured to program the magnetization directions of the first free layer and the second free layer into the second, relatively high magnetic configuration by applying a relatively large second positive electron current which is larger than the first positive electron current to the magnetoresistive memory cell to switch the first magnetic tunnel junction into the first antiparallel state and to switch the second magnetic tunnel junction into the second parallel state; and applying a relatively small second negative electron current which is smaller than the first negative current to the magnetoresistive memory cell to switch the second magnetic tunnel junction into the second antiparallel state, without disturbing the magnetization direction of the first free layer which requires the relatively large first negative current which is greater than the second negative current to switch into the first parallel state.

In the magnetoresistive memory cell 300 of the third embodiment, the first free layer 138 comprises a positive spin polarization material and the second free layer 338 comprises a negative spin polarization material. In one embodiment, the positive spin polarization material comprises Fe, Co, Ni or an alloy thereof; and the negative spin polarization material comprises Fe₁₋ₓCrₓ where x<0.7, a Mn₂VGa Heusler alloy, Fe₄N or SrRuO₃.

In the third embodiment, the programming circuit is configured to program magnetization directions of the first free layer 138 and the second free layer 338 into two magnetic configurations comprising a first, relatively low resistance magnetic configuration in which the first magnetic tunnel junction 130 is in the first parallel state and the second magnetic tunnel junction 230 is in the second antiparallel state; and a second, relatively high resistance magnetic configuration in which the first magnetic tunnel junction 130 is in the first antiparallel state and the second magnetic tunnel junction 230 is in the second parallel state, wherein the relatively high resistance is higher than the relatively low resistance.

In the third embodiment, the programing circuit is configured to program the magnetization directions of the first free layer and the second free layer into the first, relatively low resistance magnetic configuration by applying a negative electron current to the magnetoresistive memory cell 300 to switch the first magnetic tunnel junction 130 to the first parallel state and to switch the second magnetic tunnel junction 230 to the second antiparallel state. The programing circuit is configured to program the magnetization directions of the first free layer and the second free layer into the second, relatively high resistance magnetic configuration by applying a positive electron current to the magnetoresistive memory cell 300 to switch the first magnetic tunnel junction 130 to the first antiparallel state and to switch the second magnetic tunnel junction 230 into the second parallel state.

According to the first embodiment, a dual free layer, multi-level magnetoresistive memory cell 100 has more than two (e.g., three or four) distinct resistive (i.e., memory) states. The magnetoresistive memory cell 100 comprises a series connection of two magnetic tunnel junctions (130, 230), each containing independently switchable free layers (138, 238) at the top and bottom, with two centrally shared reference layers (132, 232) connected by a common magnetic polarizer layer 120 (e.g., a magnetic hard layer).

According to the second and third embodiments of the present disclosure, the dual free layer magnetoresistive memory cell (200, 300) has two distinct resistive (i.e., memory) states with an increased read signal compared to a single free layer STT memory cell. In the third embodiment, a first free layer 138 may comprise a positive spin polarization material, and a second free layer 238 may comprise a negative spin polarization material to permit one step programming of the memory cell into the relatively low and relatively high resistance states.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of”' or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or magnetic configuration is illustrated in the present disclosure, it is understood that the present disclosure may be practiced with any other compatible structures and/or magnetic configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A magnetoresistive memory cell, comprising:
a magnetic polarizer layer having a hard magnetization along a hard magnetization direction;
a first magnetic tunnel junction located on a first side of the magnetic polarizer layer and comprising a first reference layer having a first side facing the magnetic polarizer layer, a first free layer facing a second side of the first reference layer, and a first tunnel barrier layer located between the first free layer and the first reference layer; and
a second magnetic tunnel junction located on a second side of the magnetic polarizer layer and comprising a second reference layer having a second side facing the magnetic polarizer layer, a second free layer facing a first side of the second reference layer, and a second tunnel barrier layer located between the second free layer and the second reference layer.

2. The magnetoresistive memory cell of claim 1, wherein:
the first reference layer faces the first side of the magnetic polarizer layer, is antiferromagnetically coupled to the magnetic polarizer layer, and has a first fixed magnetization direction that is antiparallel to the hard magnetization direction; and
the second reference layer faces the second side of the magnetic polarizer layer, antiferromagnetically coupled to the magnetic polarizer layer, and has a second fixed magnetization direction that is antiparallel to the hard magnetization direction.

3. The magnetoresistive memory cell of claim 2, wherein:
the first magnetic tunnel junction has a first parallel state resistance when a magnetization direction of the first free layer is parallel to the first fixed magnetization direction; and
the second magnetic tunnel junction has a second parallel state resistance when a magnetization direction of the second free layer is parallel to the second fixed magnetization direction.

4. The magnetoresistive memory cell of claim 3, wherein the first free layer and the second free layer both comprise a positive spin polarization material.

5. A magnetoresistive memory device comprising the magnetoresistive memory cell of claim 4 and a programming circuit configured to program magnetization directions of the first free layer and the second free layer into two magnetic configurations comprising:
a first, relatively low resistance magnetic configuration in which the first magnetic tunnel junction is in the first parallel state and the second magnetic tunnel junction is in the second parallel state; and
a second, relatively high resistance magnetic configuration in which the first magnetic tunnel junction is in the first antiparallel state and the second magnetic tunnel junction is in the second antiparallel state, wherein the relatively high resistance is higher than the relatively low resistance.

6. The magnetoresistive memory device of claim 5, wherein the programing circuit is configured to program the magnetization directions of the first free layer and the second free layer into the first, relatively low resistance magnetic configuration by:
applying a relatively large first negative electron current to the magnetoresistive memory cell that flows in a first direction from the first reference layer to the first free layer, to switch the first magnetic tunnel junction into the first parallel state; and
applying a relatively small first positive electron current to the magnetoresistive memory cell that flows in a second direction from the second reference layer to the second free layer, which is opposite to the first direction, to switch the second magnetic tunnel junction into the second parallel state without disturbing the magnetization direction of the first free layer which requires a relatively large second positive electron current which is greater than the first positive electron current to switch into the first antiparallel state.

7. The magnetoresistive memory device of claim 6, wherein the programing circuit is configured to program the magnetization directions of the first free layer and the second free layer into the second, relatively high magnetic configuration by:
applying a relatively large second positive electron current which is larger than the first positive electron current to the magnetoresistive memory cell to switch the first magnetic tunnel junction into the first antiparallel state and to switch the second magnetic tunnel junction into the second parallel state; and
applying a relatively small second negative electron current which is smaller than the first negative current to the magnetoresistive memory cell to switch the second magnetic tunnel junction into the second antiparallel state, without disturbing the magnetization direction of the first free layer which requires the relatively large first negative current which is greater than the second negative current to switch into the first parallel state.

8. The magnetoresistive memory cell of claim 3, wherein the first free layer comprises a positive spin polarization material and the second free layer comprises a negative spin polarization material.

9. A magnetoresistive memory device comprising the magnetoresistive memory cell of claim 8 and a programming circuit configured to program magnetization directions of the first free layer and the second free layer into two magnetic configurations comprising:
a first, relatively low resistance magnetic configuration in which the first magnetic tunnel junction is in the first parallel state and the second magnetic tunnel junction is in the second antiparallel state; and
a second, relatively high resistance magnetic configuration in which the first magnetic tunnel junction is in the first antiparallel state and the second magnetic tunnel junction is in the second parallel state, wherein the relatively high resistance is higher than the relatively low resistance.

10. The magnetoresistive memory device of claim 9, wherein the programing circuit is configured to program the magnetization directions of the first free layer and the second free layer into the first, relatively low resistance magnetic configuration by applying a negative electron current to the magnetoresistive memory cell to switch the first magnetic tunnel junction to the first parallel state and to switch the second magnetic tunnel junction to the second antiparallel state.

11. The magnetoresistive memory device of claim 10, wherein the programing circuit is configured to program the magnetization directions of the first free layer and the second free layer into the second, relatively high resistance magnetic configuration by applying a positive electron current to the magnetoresistive memory cell to switch the first magnetic tunnel junction to the first antiparallel state and to switch the second magnetic tunnel junction into the second parallel state.

12. The magnetoresistive memory cell of claim 1, wherein:
the positive spin polarization material comprises Fe, Co, Ni or an alloy thereof; and
the negative spin polarization material comprises Fe₁₋ₓCrₓ where x<0.7, a Mn₂VGa Heusler alloy, Fe₄N or SrRuO₃.

13. The magnetoresistive memory cell of claim 1, wherein the magnetoresistive memory cell further comprises a selector element.

14. The magnetoresistive memory cell of claim 13, wherein the magnetoresistive memory cell further comprises:
a first antiferromagnetic coupling layer located between the magnetic polarizer layer and the first reference layer and providing the antiferromagnetic coupling therebetween; and
a second antiferromagnetic coupling layer located between the magnetic polarizer layer and the second reference layer and providing the antiferromagnetic coupling therebetween.

15. The magnetoresistive memory cell of claim 1, wherein the magnetic polarizer layer comprises a hard magnet layer.

16. The magnetoresistive memory cell of claim 1, wherein:
the first reference layer underlies the magnetic polarizer layer;
the first free layer underlies the first reference layer;
the second reference layer overlies the magnetic polarizer layer; and the second free layer overlies the second reference layer.

17. A method, comprising programming the magnetoresistive memory cell of claim 4 into two different memory states comprising:
a first, relatively low resistance memory state in which the first magnetic tunnel junction is in a first parallel state and the second magnetic tunnel junction is in a second parallel state; and
a second, relatively high resistance memory state in which the first magnetic tunnel junction is in the first antiparallel state and the second magnetic tunnel junction is in the second antiparallel state.

18. The method of claim 17, comprising:
programming the magnetoresistive memory cell into the first, relatively low resistance memory state by:
applying a relatively large first negative electron current to the magnetoresistive memory cell that flows in a first direction from the first reference layer to the first free layer, to switch the first magnetic tunnel junction into the first parallel state; and
applying a relatively small first positive electron current to the magnetoresistive memory cell that flows in a second direction from the second reference layer to the second free layer, which is opposite to the first direction, to switch the second magnetic tunnel junction into the second parallel state without disturbing the magnetization direction of the first free layer which requires a relatively large second positive electron current which is greater than the first positive electron current to switch into the first antiparallel state.
programming the magnetoresistive memory cell into the second, relatively high resistance memory state by:
applying a relatively large second positive electron current which is larger than the first positive electron current to the magnetoresistive memory cell to switch the first magnetic tunnel junction into the first antiparallel state and to switch the second magnetic tunnel junction into the second parallel state; and
applying a relatively small second negative electron current which is smaller than the first negative current to the magnetoresistive memory cell to switch the second magnetic tunnel junction into the second antiparallel state, without disturbing the magnetization direction of the first free layer which requires the relatively large first negative current which is greater than the second negative current to switch into the first parallel state.

19. A method, comprising programming the magnetoresistive memory cell of claim 8 into two different memory states comprising:
a first, relatively low resistance memory state in which the first magnetic tunnel junction is in a first parallel state and the second magnetic tunnel junction is in a second antiparallel state; and
a second, relatively high resistance memory state in which the first magnetic tunnel junction is in the first antiparallel state and the second magnetic tunnel junction is in the second parallel state.

20. The method of claim 19, comprising:
programming the magnetoresistive memory cell into the first, relatively low resistance memory state by applying a negative electron current to the magnetoresistive memory cell to switch the first magnetic tunnel junction to the first parallel state and to switch the second magnetic tunnel junction to the second antiparallel state; and
programming the magnetoresistive memory cell into the second, relatively high resistance memory state by applying a positive electron current to the magnetoresistive memory cell to switch the first magnetic tunnel junction to the first antiparallel state and to switch the second magnetic tunnel junction into the second parallel state.
